(19) United States
(12) Patent Application Publication
(10) Pub. No.: US 2025/0329353 A1
(43) Pub. Date: Oct. 23, 2025

(54) VARIABLE RESISTANCE MEMORY DEVICE INCLUDING PROTRUSIONS AND RECESSES

(71) Applicant: SAMSUNG ELECTRONICS CO., LTD., SUWON-SI (KR)

(72) Inventors: Kilho LEE, Suwon-si (KR); Yongjae KIM, Suwon-si (KR); Junhoe KIM, Suwon-si (KR); Kyounghun RYU, Suwon-si (KR); Junho PARK, Suwon-si (KR); Byoungjae BAE, Suwon-si (KR); Myoungsu SON, Suwon-si (KR); Jihyeon JEON, Suwon-si (KR); Hyeonah JO, Suwon-si (KR)

(21) Appl. No.: 19/038,977

(22) Filed: Jan. 28, 2025

(30) Foreign Application Priority Data
Apr. 17, 2024 (KR) 10-2024-0051173

(51) Int. Cl. G11C 5/06; G11C 5/08; G11C 11/16; H10B 61/00; H10N 50/10

(52) U.S. Cl. CPC G11C 5/063; G11C 5/08; G11C 11/1675; H10B 61/22; H10N 50/10

(57) ABSTRACT

A variable resistance memory device includes: a substrate; a plurality of wiring contacts arranged on the substrate; an isolation insulating layer disposed on the plurality of wiring contacts; and a plurality of variable resistance pattern structures arranged on the isolation insulating layer, wherein the plurality of variable resistance pattern structures constitute a plurality of memory cells, and are spaced apart from one another in a horizontal direction, wherein the isolation insulating layer includes a protrusion that is defined by an isolation recess, and wherein four adjacent variable resistance pattern structures among the plurality of variable resistance pattern structures are respectively arranged at four vertices of a square, and the protrusion is arranged in a central region of the square.

### CROSS-REFERENCE TO RELATED APPLICATION

This application claims priority under 35 U.S.C. § 119 to Korean Patent Application No. 10-2024-0051173, filed on Apr. 17, 2024, in the Korean Intellectual Property Office, the disclosure of which is incorporated by reference herein in its entirety.

### TECHNICAL FIELD

The present inventive concept relates to a variable resistance memory device, and more particularly, to a variable resistance memory device including protrusions and recesses.

### DISCUSSION OF THE RELATED ART

As the electronic industry further develops, memory devices with increased operating speed and integration are becoming increasingly desirable for semiconductor products. To satisfy these desires, variable resistance memory devices are currently under development. The variable resistance memory device may use current transfer characteristics of a variable resistance layer according to an applied voltage. A representative example of the variable resistance memory device may be magnetoresistive random access memory (MRAM).

### SUMMARY

According to an embodiment of the present inventive concept, a variable resistance memory device includes: a substrate; a plurality of wiring contacts arranged on the substrate; an isolation insulating layer disposed on the plurality of wiring contacts; and a plurality of variable resistance pattern structures arranged on the isolation insulating layer, wherein the plurality of variable resistance pattern structures constitute a plurality of memory cells, and are spaced apart from one another in a horizontal direction, wherein the isolation insulating layer includes a protrusion that is defined by an isolation recess, and wherein four adjacent variable resistance pattern structures among the plurality of variable resistance pattern structures are respectively arranged at four vertices of a square, and the protrusion is arranged in a central region of the square.

According to an embodiment of the present inventive concept, a variable resistance memory device includes: a substrate; a plurality of lower electrode contacts arranged on the substrate; an isolation insulating layer covering sidewalls of the plurality of lower electrode contacts; and a plurality of variable resistance pattern structures spaced apart from one another in a horizontal direction on the isolation insulating layer to form a plurality of memory cells, and connected to the plurality of lower electrode contacts, wherein the isolation insulating layer includes a protrusion that is defined by an isolation recess, wherein, among the plurality of variable resistance pattern structures, a first variable resistance pattern structure is spaced apart from a second variable resistance pattern structure by a first distance and is spaced apart from a third variable resistance pattern structure by a second distance that is greater than the first distance in a direction that is different than a direction in which the first distance extends, and wherein the protrusion is not arranged between the first variable resistance pattern structure and the second variable resistance pattern structure, and is arranged between the first variable resistance pattern structure and the third variable resistance pattern structure.

According to an embodiment of the present inventive concept, a variable resistance memory device includes: a substrate; a plurality of wiring contacts arranged on the substrate; a plurality of lower electrode contacts connected to the plurality of wiring contacts; an isolation insulating layer covering sidewalls of the plurality of lower electrode contacts and disposed on the plurality of wiring contacts, wherein the isolation insulating layer includes a first isolation insulating layer and a second isolation insulating layer covering the first isolation insulating layer; and a plurality of variable resistance pattern structures spaced apart from one another in a horizontal direction on the isolation insulating layer to form a plurality of memory cells, and connected to the plurality of lower electrode contacts, wherein the isolation insulating layer includes a protrusion that is defined by an isolation recess, wherein, among the plurality of variable resistance pattern structures, a first variable resistance pattern structure is spaced apart from a second variable resistance pattern structure by a first distance and is spaced apart from a third variable resistance pattern structure by a second distance that is greater than the first distance in a direction that is different than a direction in which the distance extends, wherein the protrusion is not arranged between the first variable resistance pattern structure and the second variable resistance pattern structure, and is arranged between the first variable resistance pattern structure and the third variable resistance pattern structure, wherein an uppermost end of the isolation insulating layer and bottom surfaces of the plurality of variable resistance pattern structures are at a substantially same vertical level as each other, but are at a higher vertical level than a top surface of the protrusion, and wherein a bottom surface of the isolation recess is at a vertical level that is lower than the top surface of the protrusion and higher than a bottom surface of the isolation insulating layer.

### BRIEF DESCRIPTION OF THE DRAWINGS

The above and other aspects of the present inventive concept will become more apparent by describing in detail embodiments thereof, with reference to the accompanying drawings, in which:

FIG. 1 is a circuit diagram illustrating a cell array of a variable resistance memory device according to an embodiment of the present inventive concept;

FIG. 2 is a circuit diagram illustrating the magnetoresistive memory cell of FIG. 1;

FIG. 3 is a perspective view of the magnetoresistive memory cell of FIG. 2;

FIGS. 4 and 5 are diagrams for describing a write operation of a magnetic tunnel junction layer constituting the magnetoresistive memory cell of FIG. 1;

FIGS. 6A, 6B, 6C, 6D, and 6E are diagrams illustrating embodiments of magnetic tunnel junction layers each constituting the magnetoresistive memory cell of FIG. 1;

FIGS. 7A and 7B are plan views illustrating a variable resistance memory device according to an embodiment of the present inventive concept;

FIGS. 8A, 8B, 8C, and 8D are cross-sectional views illustrating a method of manufacturing a variable resistance memory device according to an embodiment of the present inventive concept, FIG. 8E is a cross-sectional view illustrating a variable resistance memory device according to an embodiment of the inventive concept, FIG. 9A and FIG. 9B are cross-sectional views illustrating part of a variable resistance memory device according to an embodiment of the present inventive concept, and FIG. 9C is a plan view illustrating part of a variable resistance memory device according to an embodiment of the present inventive concept;

FIGS. 10, 11 and 12 are cross-sectional views illustrating a method of manufacturing a variable resistance memory device according to an embodiment of the present inventive concept;

FIGS. 13A and 13B are plan views illustrating a variable resistance memory device according to an embodiment of the present inventive concept;

FIGS. 14A and 14B are cross-sectional views illustrating part of a variable resistance memory device according to an embodiment of the inventive concept, and FIG. 14C is a plan view illustrating part of a variable resistance memory device according to an embodiment of the present inventive concept;

FIG. 15 is a block diagram of a variable resistance memory device according to an embodiment of the present inventive concept;

FIG. 16 is a block diagram of a data processing system including a variable resistance memory device according to an embodiment of the present inventive concept; and

FIG. 17 is a block diagram of a data processing system including a variable resistance memory device according to an embodiment of the present inventive concept.

### DETAILED DESCRIPTION OF THE EMBODIMENTS

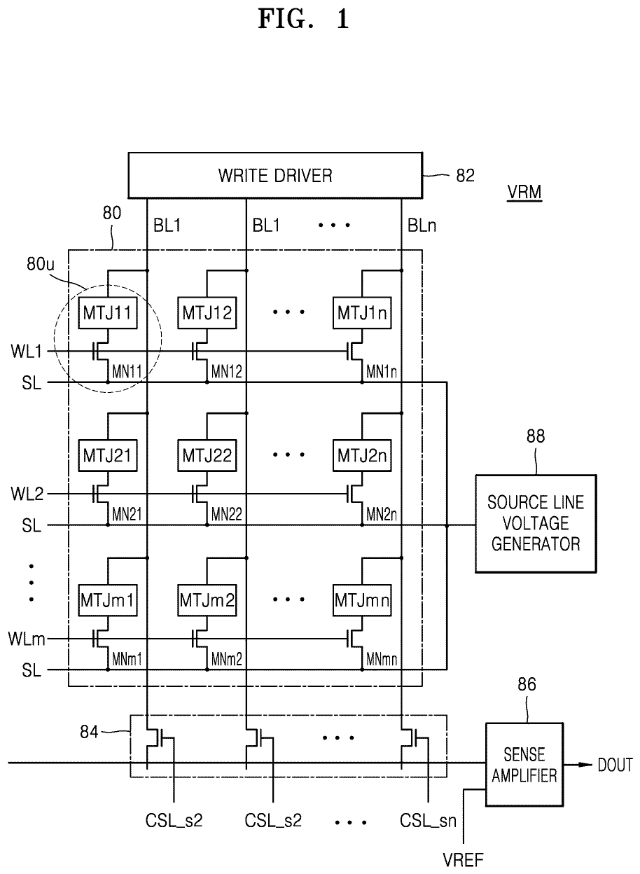

FIG. 1 is a circuit diagram illustrating a cell array of a variable resistance memory device VRM according to an embodiment of the present inventive concept.

Referring to FIG. 1, the variable resistance memory device VRM may include a magnetoresistive memory cell array 80. The magnetoresistive memory cell array 80 may be referred to as a memory cell array. The magnetoresistive memory cell array 80 may be connected to a write driver 82, a selection circuit 84, a source line voltage generator 88, and a sense amplifier 86. The magnetoresistive memory cell array 80 may include a plurality of magnetoresistive memory cells 80u. The magnetoresistive memory cell 80u may be referred to as a memory cell. The magnetoresistive memory cell array 80 may include a plurality of word lines WL1 to WLm and a plurality of bit lines BL1 to BLn. The magnetoresistive memory cell array 80 may have the magnetoresistive memory cell 80u between each of the plurality of word lines WL1 to WLm and each of the plurality of bit lines BL1 to BLn.

In embodiments of the present inventive concept, the variable resistance memory device VRM may be a magnetoresistive memory device. The magnetoresistive memory device may be a magnetoresistive random access memory (MRAM). The variable resistance memory device VRM may include a variable resistance layer. For example, the variable resistance layer may be a magnetic tunnel junction layer.

The magnetoresistive memory cell array 80 may include a plurality of cell transistors MN11 to MNmn with gates that are connected to the plurality of word lines WL1 to WLm. The magnetoresistive memory cell array 80 may further include a plurality of magnetic tunnel junction layers MTJ11 to MTJmn that is connected between the plurality of cell transistors MN11 to MNmn and the plurality of bit lines BL1 to BLn, respectively, and that forms the variable resistance layer.

Sources of the plurality of cell transistors MN11 to MNmn may be connected to a source line SL. The selection circuit 84 may selectively connect the plurality of bit lines BL1 to BLn to the sense amplifier 86 in response to a plurality of column selection signals CSL_s1 to CSL_sn. The sense amplifier 86 may amplify a difference between an output voltage signal of the selection circuit 84 and a reference voltage VREF to generate output data DOUT.

The write driver 82 is connected to the plurality of bit lines BL1 to BLn, generates a program current based on write data, and provides the program current to the plurality of bit lines BL1 to BLn. To magnetize the plurality of magnetic tunnel junction layers MTJ11 to MTJmn in the magnetoresistive memory cell array 80, a voltage higher than a voltage that is applied to the plurality of bit lines BL1 to BLn may be applied to the source line SL. The source line voltage generator 88 may generate a source line driving voltage VSL and may provide the source line driving voltage VSL to source lines SL of the magnetoresistive memory cell array 80.

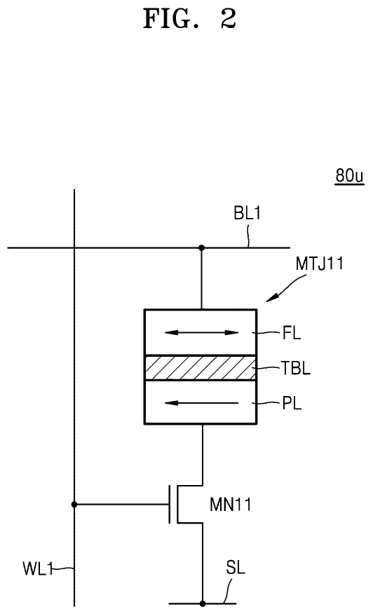

FIG. 2 is a circuit diagram illustrating the magnetoresistive memory cell of FIG. 1.

Referring to FIG. 2, the magnetoresistive memory cell 80u may include the cell transistor MN11, which includes an NMOS transistor, and the magnetic tunnel junction layer MTJ11. The cell transistor MN11 has a gate connected to the word line WL1 and a source connected to the source line SL. The magnetic tunnel junction layer MTJ11 is connected between a drain of the cell transistor MN11 and the bit line BL1.

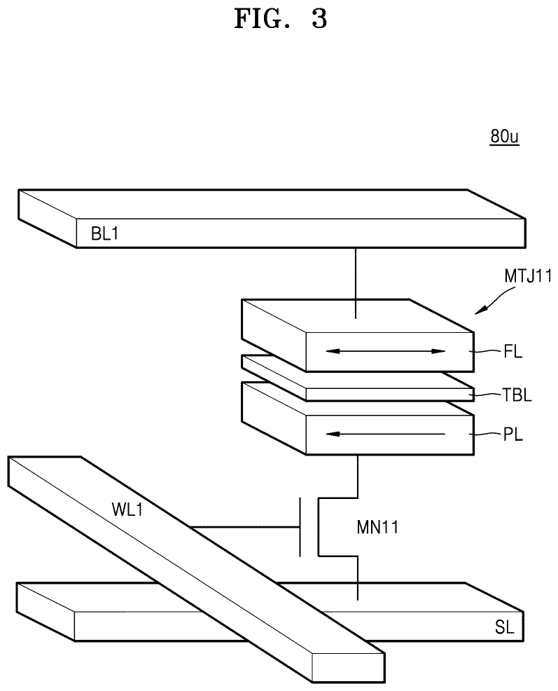

FIG. 3 is a perspective view of the magnetoresistive memory cell of FIG. 2.

Referring to FIG. 3, the magnetic tunnel junction layer MTJ11 may include a pinned layer PL, which has a fixed magnetization direction, a free layer FL magnetized in a direction of a magnetic field, which is applied from the outside, and a tunnel barrier layer TBL that is formed as an insulating layer between the pinned layer PL and the free layer FL.

The magnetic tunnel junction layer MTJ11 may be included in a cell constituting STT-MRAM. To perform a write operation of STT-MRAM, a logic high voltage may be applied to the word line WL1 to turn on the cell transistor MN11, and a write current may be applied between the bit line BL1 and the source line SL.

To perform a read operation of STT-MRAM, a logic high voltage is applied to the word line WL1 to turn on the cell transistor MN11, and a read current is applied from the bit line BL1 to the source line SL to determine data stored in the magnetoresistive memory cell 80u according to a resistance value of the magnetic tunnel junction layer MTJ11 for the read current.

The resistance value of the magnetic tunnel junction layer MTJ11 varies according to the magnetization direction of the free layer FL. For example, in the magnetic tunnel junction layer MTJ11, the magnetization direction of the free layer FL may be parallel to a magnetization direction of the pinned layer PL. In this case, the magnetic tunnel junction layer MTJ11 has a low resistance value and may read data ‘0’. In addition, in the magnetic tunnel junction layer MTJ11, the magnetization direction of the free layer FL may be anti-parallel to the magnetization direction of the pinned layer PL. In this case, the magnetic tunnel junction layer MTJ11 has a high resistance value and may read data ‘1’.

In FIGS. 2 and 3, the magnetoresistive memory cell 80u is illustrated as being a horizontal magnetic device in which the magnetization directions of the free layer FL and the pinned layer PL of the magnetic tunnel junction layer MTJ11 are horizontal, but may be a vertical magnetic device in which the magnetization directions of the free layer FL and the pinned layer PL of the magnetic tunnel junction layer MTJ11 are vertical according to an embodiment of the present invention, as described later.

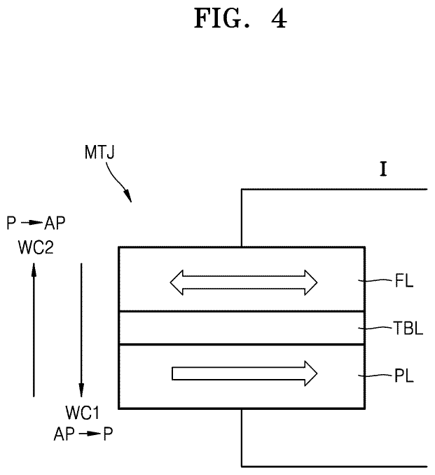

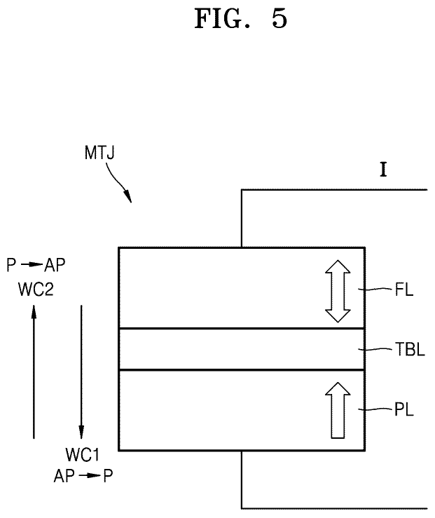

FIGS. 4 and 5 are diagrams for describing a write operation of a magnetic tunnel junction layer MTJ constituting the magnetoresistive memory cell of FIG. 1.

Referring to FIG. 4, the magnetic tunnel junction layer MTJ may constitute a horizontal magnetic device in which the magnetization directions of the free layer FL and the pinned layer PL are horizontal. The magnetic tunnel junction layer MTJ with a horizontal magnetization direction may have a current movement direction and an easy axis of magnetization that is substantially vertical.

Referring to FIG. 5, the magnetic tunnel junction layer MTJ may constitute a vertical magnetic device in which the magnetization directions of the free layer FL and the pinned layer PL are vertical. The magnetic tunnel junction layer MTJ with a vertical magnetization direction may have a current movement direction and an easy axis of magnetization that is substantially horizontal.

Referring to FIGS. 4 and 5 together, the magnetization direction of the free layer FL may be determined according to directions of first and second write currents WC1 and WC2 flowing through the magnetic tunnel junction layer MTJ. For example, when the first write current WC1 is applied, free electrons with the same spin direction as the pinned layer PL may apply torque to the free layer FL. As a result, the free layer FL may be magnetized parallel to the pinned layer PL.

When the second write current WC2 is applied, electrons with a spin that is opposite to that of the pinned layer PL return to the free layer FL and apply torque. As a result, the free layer FL may be magnetized anti-parallel to the pinned layer PL. That is, the magnetization direction of the free layer FL in the magnetic tunnel junction layer MTJ may be changed by spin transfer torque (STT).

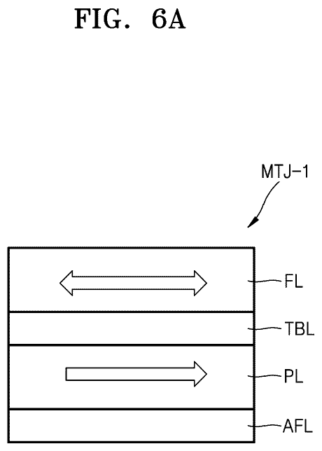

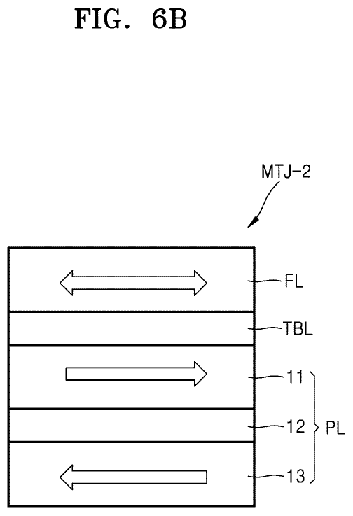

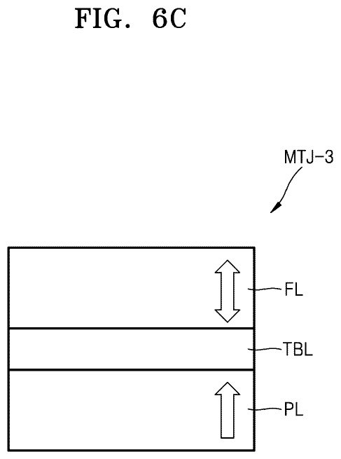

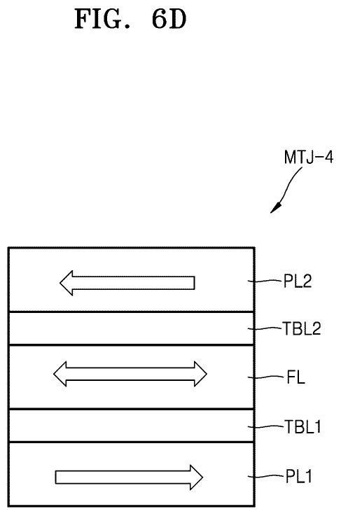

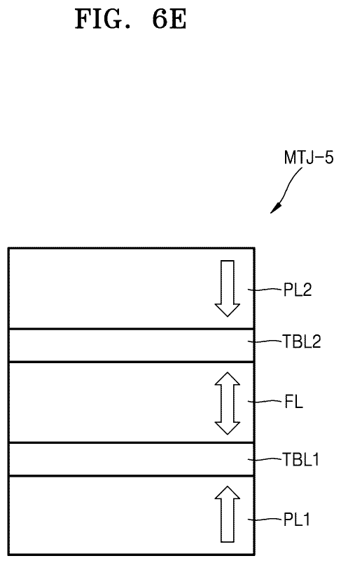

FIGS. 6A to 6E are diagrams illustrating various embodiments of magnetic tunnel junction layers MTJ-1, MTJ-2, MTJ-3, MTJ-4, and MTJ-5 each constituting the magnetoresistive memory cell of FIG. 1.

Referring to FIG. 6A, the magnetic tunnel junction layer MTJ-1 may include a free layer FL, a tunnel barrier layer TBL, a pinned layer PL, and an anti-ferromagnetic layer AFL. The magnetic tunnel junction layer MTJ-1 may be a single magnetic tunnel junction layer. The magnetic tunnel junction layer MTJ-1 may constitute a horizontal magnetic device in which magnetization directions of the free layer FL and the pinned layer PL are horizontal. In embodiments of the present inventive concept, the magnetic tunnel junction layer MTJ-1 may include the free layer FL, the tunnel barrier layer TBL, and the pinned layer PL and may not include the anti-ferromagnetic layer AFL.

The free layer FL may include a material with a changeable magnetization direction. The magnetization direction of the free layer FL may be changed by electrical/magnetic factors that are provided outside and/or inside the magnetoresistive memory cell. The free layer FL may include a ferromagnetic material including at least one of cobalt (Co), iron (Fe), and/or nickel (Ni). For example, the free layer FL may include at least one of FeB, Fe, Co, Ni, Gd, Dy, CoFe, NiFe, MnAs, MnBi, MnSb, CrO₂, MnOFe₂O₃, FeOFe₂O₃, NiOFe₂O₃, CuOFe₂O₃, MgOFe₂O₃, EuO, and/or Y₃Fe₅O₁₂.

The tunnel barrier layer TBL may have a thickness that is less than a spin diffusion distance. The tunnel barrier layer TBL may include a non-magnetic material. For example, the tunnel barrier layer TBL may include at least one of oxides of magnesium (Mg), titanium (Ti), aluminum (Al), magnesium-zinc (MgZn), magnesium-boron (MgB), and/or nitrides of titanium (Ti) and vanadium (V).

The pinned layer PL may have a fixed magnetization direction. In embodiments of the present inventive concept, the pinned layer PL may have a magnetization direction fixed by the antiferromagnetic layer AFL. The pinned layer PL may include a ferromagnetic material. For example, the pinned layer PL may include at least one of CoFeB, Fe, Co, Ni, Gd, Dy, CoFe, NiFe, MnAs, MnBi, MnSb, CrO₂, MnOFe₂O₃, FeOFe₂O₃, NiOFe₂O₃, CuOFe₂O₃, MgOFe₂O₃, EuO, and/or Y₃Fe₅O₁₂.

The anti-ferromagnetic layer AFL may include an anti-ferromagnetic material. For example, the anti-ferromagnetic layer AFL may include at least one of PtMn, IrMn, MnO, MnS, MnTe, MnF₂, FeCl₂, FeO, CoCl₂, CoO, NiCl₂, NiO, and chromium (Cr).

Referring to FIG. 6B, the magnetic tunnel junction layer MTJ-2 may include a free layer FL, a tunnel barrier layer TBL, and a pinned layer PL. The magnetic tunnel junction layer MTJ-2 may constitute a horizontal magnetic device in which magnetization directions of the free layer FL and the pinned layer PL are horizontal. The pinned layer PL may be provided as a synthetic anti-ferromagnetic (SAF) material. The pinned layer PL may include a first ferromagnetic layer 11, a bonding layer 12, and a second ferromagnetic layer 13. Each of the first ferromagnetic layer 11 and the second ferromagnetic layer 13 may include, for example, at least one pf CoFeB, Fe, Co, Ni, Gd, Dy, CoFe, NiFe, MnAs, MnBi, MnSb, CrO₂, MnOFe₂O₃, FeOFe₂O₃, NiOFe₂O₃, CuOFe₂O₃, MgOFe₂O₃, EuO, and/or Y₃Fe₅O₁₂. A magnetization direction of the first ferromagnetic layer 11 may be different from a magnetization direction of the second ferromagnetic layer 13. The magnetization direction of each of the first ferromagnetic layer 11 and the second ferromagnetic layer 13 may be fixed. For example, the bonding layer 12 may include ruthenium (Ru).

Referring to FIG. 6C, the magnetic tunnel junction layer MTJ-3 may include a free layer FL, a tunnel barrier layer TBL, and a pinned layer PL. The magnetic tunnel junction layer MTJ-3 may be a single magnetic tunnel junction layer. The magnetic tunnel junction layer MTJ-3 may constitute a vertical magnetic device in which magnetization directions of the free layer FL and the pinned layer PL are vertical. To implement the magnetic tunnel junction layer MTJ-3 with a vertical magnetization direction, the free layer FL and the pinned layer PL may include a material with high magnetic anisotropy energy. For example, each of the free layer (FL) and the fixed layer (PL) may include a material with high magnetic anisotropy energy, such as an amorphous rare earth element alloy or a multilayer thin film such as (Co/Pt) n or (Fe/Pt) n.

For example, the free layer FL may be an ordered alloy and may include at least one of Fe, Co, Ni, palladium (Pa), and platinum (Pt). For example, the free layer FL may include at least one of a Fe—Pt alloy, a Fe—Pd alloy, a Co—Pd alloy, a Co—Pt alloy, a Fe—Ni—Pt alloy, a Co—Fe—Pt alloy, and/or a Co—Ni—Pt alloy. The alloy included in the free layer FL may be, for example, Fe₅₀Pt₅₀, Fe₅₀Pd₅₀, Co₅₀Pd₅₀, Co₅₀Pt₅₀, Fe₃₀Ni₂₀Pt₅₀, Co₃₀Fe₂₀Pt₅₀, or Co₃₀Ni₂₀Pt₅₀ in chemical quantitative terms.

The pinned layer PL may be an ordered alloy and may include at least one of, for example, Fe, Co, Ni, Pa, and Pt. For example, the pinned layer PL may include at least one of a Fe—Pt alloy, a Fe—Pd alloy, a Co—Pd alloy, a Co—Pt alloy, a Fe—Ni—Pt alloy, a Co—Fe—Pt alloy, and/or a Co—Ni—Pt alloy. The alloy included in the pinned layer PL may be, for example, Fe₅₀Pt₅₀, Fe₅₀Pd₅₀, Co₅₀Pd₅₀, Co₅₀Pt₅₀, Fe₃₀Ni₂₀Pt₅₀, Co₃₀Fe₂₀Pt₅₀, or Co₃₀Ni₂₀Pt₅₀ in chemical quantitative terms.

Referring to FIG. 6D, the magnetic tunnel junction layer MTJ-4 may include a first pinned layer PL1, a first tunnel barrier layer TBL1, a free layer FL, a second tunnel barrier layer TBL2, and a second pinned layer PL2. The magnetic tunnel junction layer MTJ-4 may be a dual magnetic tunnel junction layer. The magnetic tunnel junction layer MTJ-4 may constitute a horizontal magnetic device in which magnetization directions of the first pinned layer PL1, the free layer FL, and the second pinned layer PL2 are horizontal. The magnetic tunnel junction layer MTJ-4 has a structure in which the first tunnel barrier layer TBL1 and the first pinned layer PL1 are sequentially arranged at one side of the free layer FL, and the second tunnel barrier layer TBL2 and the second pinned layer PL2 are sequentially arranged at the other side of the free layer FL. The material constituting each of the free layer FL, the material constituting the first pinned layer PL1 and the second pinned layer PL2, and the material constituting the first tunnel barrier layer TBL1 and the second tunnel barrier layer TBL2 may be the same as or similar to the material constituting each of the free layer FL, the material constituting the pinned layer PL, and the material constituting the tunnel barrier layer TBL described in FIG. 6A.

When the magnetization direction of the first pinned layer PL1 and the magnetization direction of the second pinned layer PL2 are fixed in opposite directions, magnetic force caused by the first pinned layer PL1 and the second pinned layer PL2 is substantially offset. Therefore, the magnetic tunnel junction layer MTJ-4 may perform a write operation by using a current that is less than that of the magnetic tunnel junction layer MTJ-1 illustrated in FIG. 6A. In addition, because the dual magnetic tunnel junction layer MTJ-4 provides higher resistance during read operation due to the second tunnel barrier layer TBL2, clear data values may be obtained.

Referring to FIG. 6E, the magnetic tunnel junction layer MTJ-5 may include a first pinned layer PL1, a first tunnel barrier layer TBL1, a free layer FL, a second tunnel barrier layer TBL2, and a second pinned layer PL2. The magnetic tunnel junction layer MTJ-5 may be a dual magnetic tunnel junction layer. The magnetic tunnel junction layer MTJ-5 may constitute a vertical magnetic device in which magnetization directions of the first pinned layer PL1, the free layer FL, and the second pinned layer PL2 are vertical. The magnetic tunnel junction layer MTJ-5 has a structure in which the first tunnel barrier layer TBL1 and the first pinned layer PL1 are sequentially arranged at one side of the free layer FL, and the second tunnel barrier layer TBL2 and the second pinned layer PL2 are sequentially arranged at the other side of the free layer FL. For example, the free layer FL may be disposed between the first tunnel barrier layer TBL1 and the second tunnel barrier layer TBL2. The material constituting each of the free layer FL, the material constituting the first pinned layer PL1 and the second pinned layer PL2, and the material constituting each of the first tunnel barrier layer TBL1 and the second tunnel barrier layer TBL2 may be the same as or similar to the material constituting each of the free layer FL, and the material constituting the pinned layer PL, and the material constituting the tunnel barrier layer TBL described in FIG. 6C.

When the magnetization direction of the first pinned layer PL1 and the magnetization direction of the second pinned layer PL2 are fixed in opposite directions, magnetic force caused by the first pinned layer PL1 and the second pinned layer PL2 is substantially offset. Therefore, the magnetic tunnel junction layer MTJ-5 may perform a write operation by using a current that is less than that of the magnetic tunnel junction layer MTJ-3 illustrated in FIG. 6C.

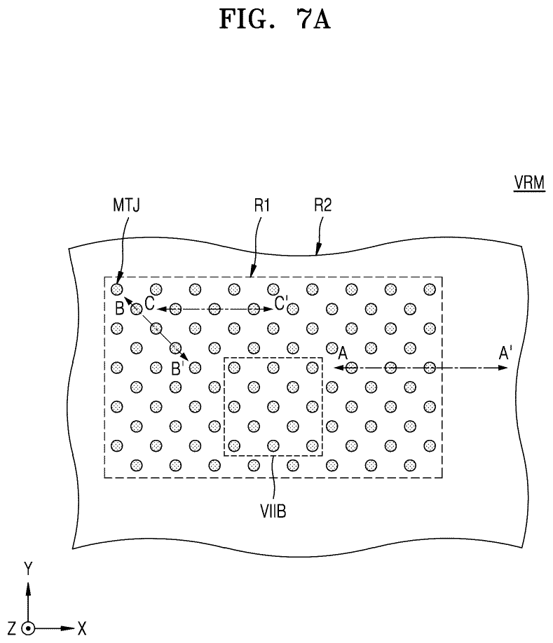

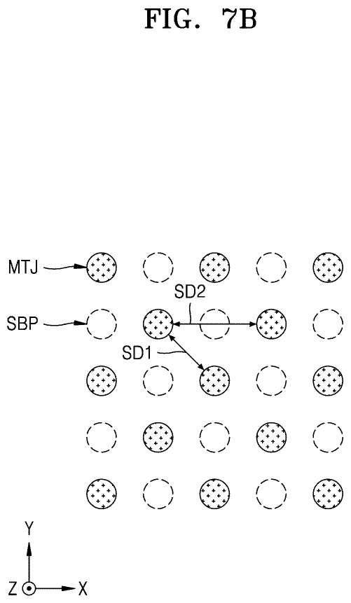

FIGS. 7A and 7B are plan views illustrating a variable resistance memory device VRM according to an embodiment of the present inventive concept. Specifically, FIG. 7B is a plan view illustrating an arrangement of some components of the portion VIIB of FIG. 7A.

Referring to FIGS. 7A and 7B together, the variable resistance memory device VRM may be a magnetoresistive memory device. The variable resistance memory device VRM may include a first region R1 and a second region R2. The first region R1 may be a cell array region in which memory cells, that is, magnetoresistive memory cells, are formed. The second region R2 may be positioned around the first region R1 and may be a peripheral circuit region in which core/peripheral circuits are formed. In embodiments of the present inventive concept, in a plan view, the second region R2 may completely surround the first region R1.

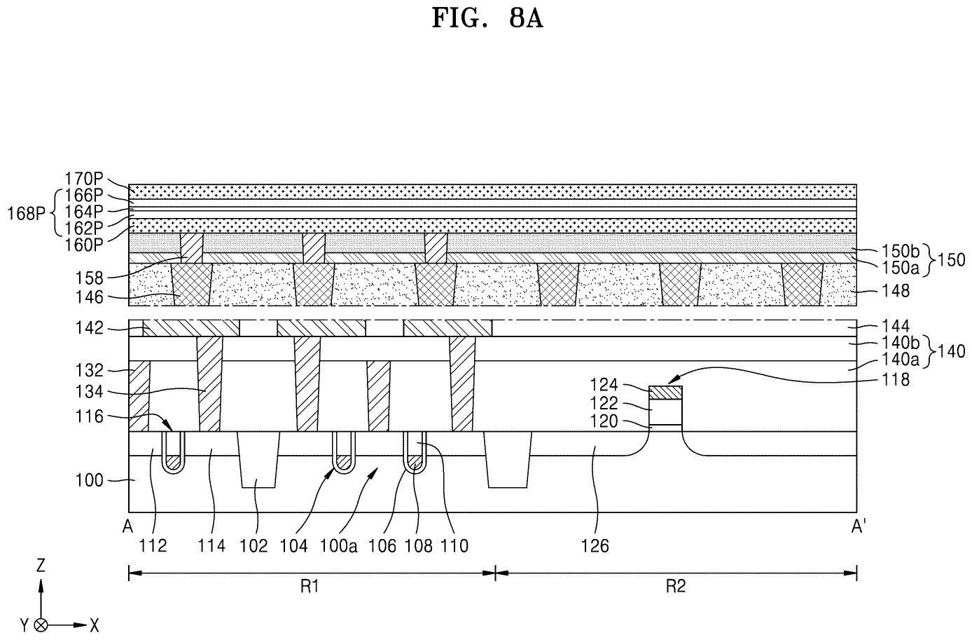

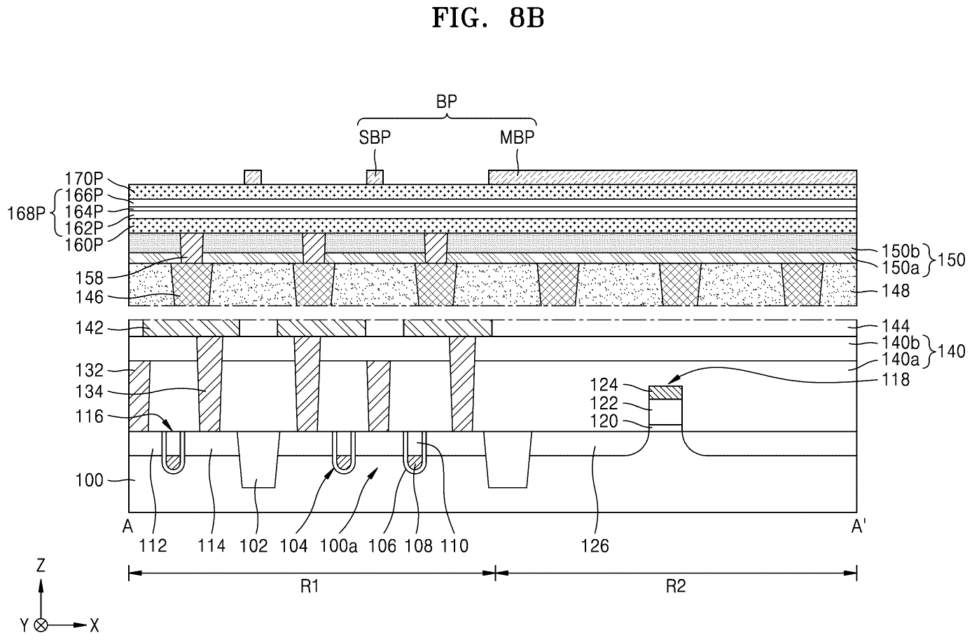

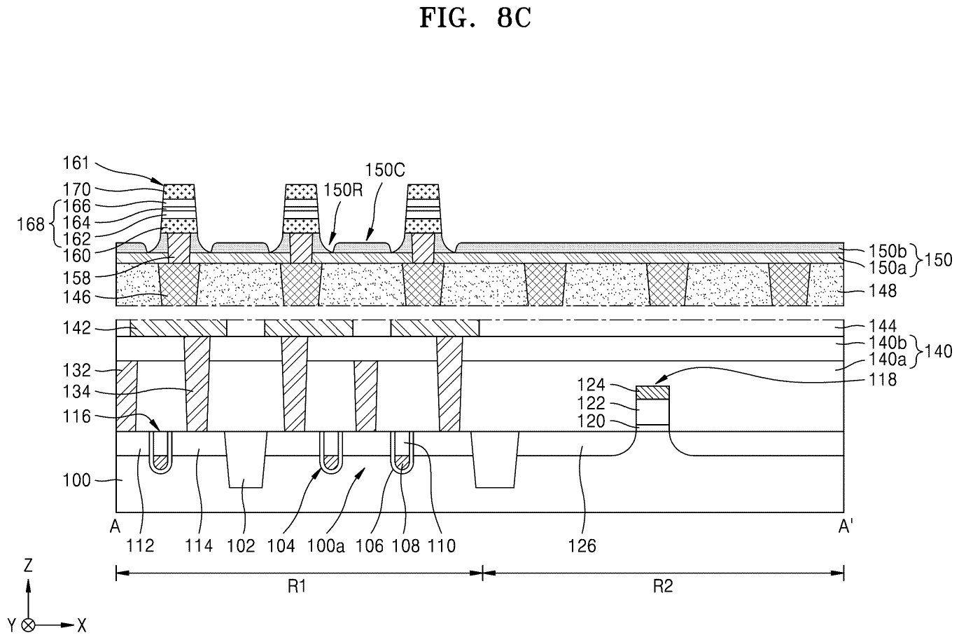

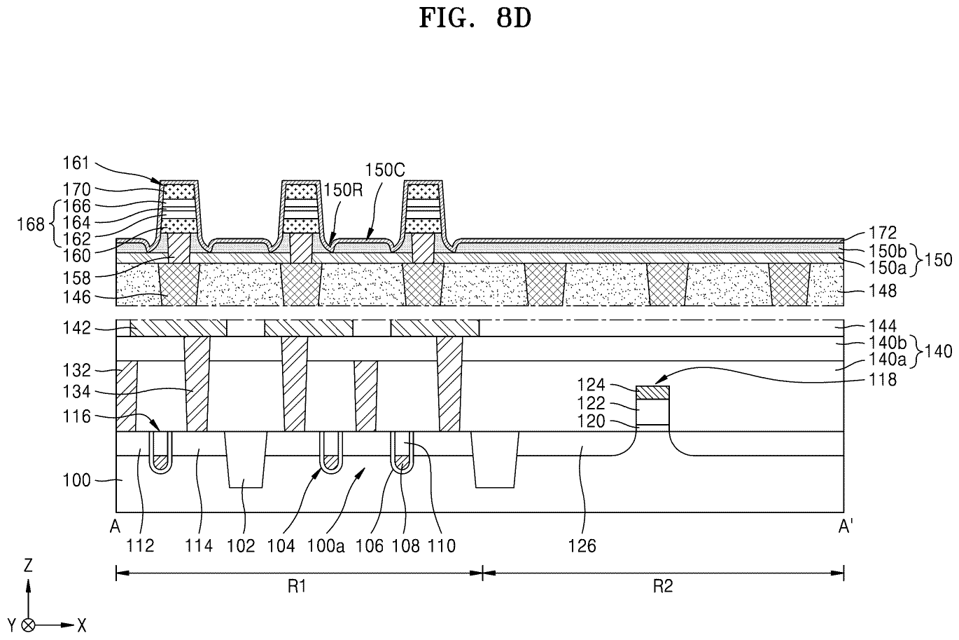

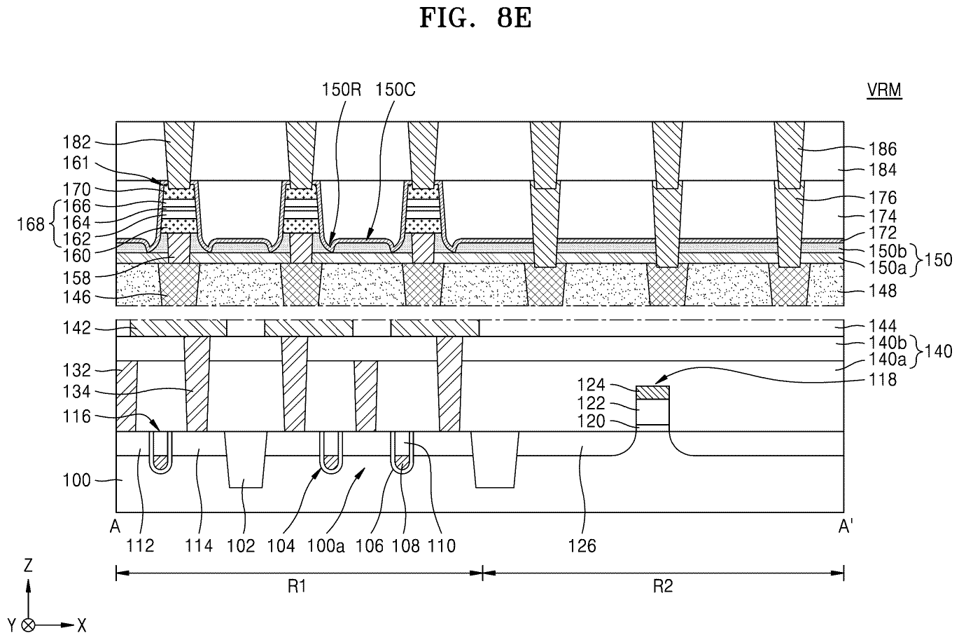

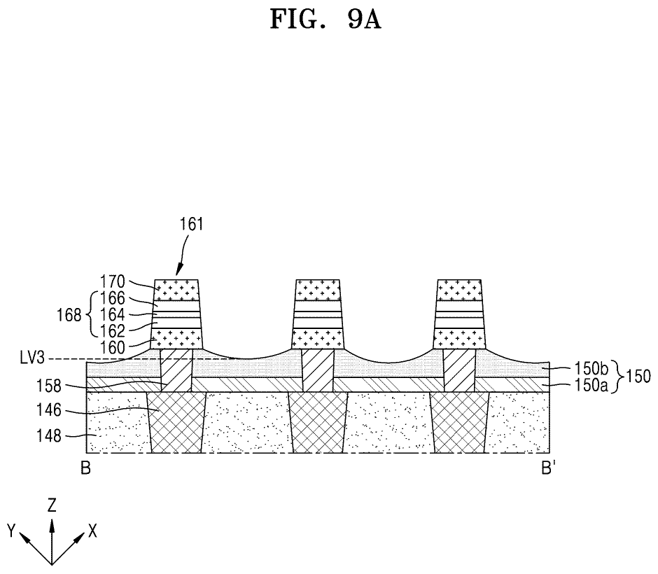

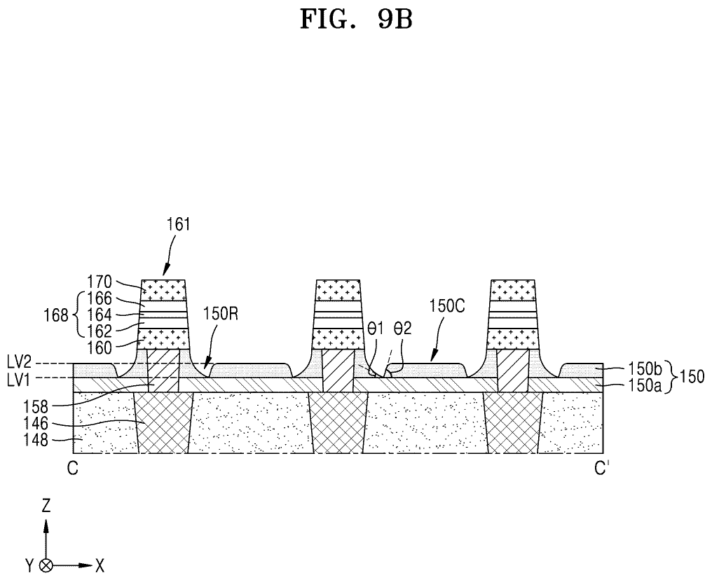

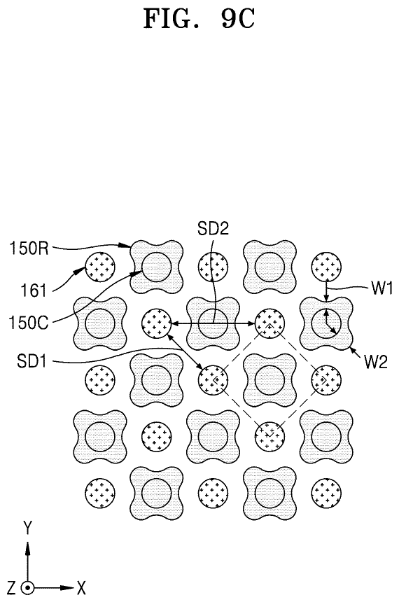

The first region R1 may include active regions 100a of FIG. 8E, each which has an isolated island shape and are regularly arranged in a first horizontal direction (X direction) and a second horizontal direction (Y direction). Two first transistors 116 of FIG. 8E may be provided in each of the active regions 100a. The first horizontal direction (X direction) may be different from the second horizontal direction (Y direction). In embodiments of the present inventive concept, the first horizontal direction (X direction) and the second horizontal direction (Y direction) may be orthogonal to each other.

The second region R2 may include a second transistor 118 of FIG. 8E constituting core/peripheral circuits. The second transistor 118 may include a second gate insulating layer pattern 120 of FIG. 8E, a second gate electrode 122 of FIG. 8E, and a second source/drain region 126 of FIG. 8E as described later.

A plurality of magnetic tunnel junction layers MTJ may be arranged in the first region R1. The plurality of magnetic tunnel junction layers MTJ may be arranged in a honeycomb shape that is arranged in zigzags in the first horizontal direction (X direction) or the second horizontal direction (Y direction). For example, the plurality of magnetic tunnel junction layers MTJ may be arranged in a row in the first horizontal direction (X direction) and may be arranged in zigzags in the second horizontal direction (Y direction). For example, the plurality of magnetic tunnel junction layers MTJ may have an alternating arrangement. In embodiments of the present inventive concept, a plurality of lower electrodes 210 may have a matrix arrangement in the first horizontal direction (X direction) and the second horizontal direction (Y direction).

The magnetic tunnel junction layer MTJ may include a variable resistance layer. For example, the magnetic tunnel junction layer MTJ may include the magnetic tunnel junction layers MTJ11 to MTJmn, MTJ, MTJ-1, MTJ-2, MTJ-3, MTJ-4, and MTJ-5, or the magnetic tunnel junction pattern 168 illustrated in each of FIGS. 8E, 9A, and 9B.

In a plan view, four adjacent magnetic tunnel junction layers MTJ among the plurality of magnetic tunnel junction layers MTJ may be arranged at four vertices of a square. For example, each of four sides of the square, in which the four adjacent magnetic tunnel junction layers MTJ are arranged at the four vertices in a plan view, may extend in a diagonal direction with respect to each of the first horizontal direction (X direction) and the second horizontal direction (Y direction). In a process of forming the variable resistance memory device VRM, a sub-blocking pattern SBP may be arranged in a center or central region of the square formed by the four adjacent magnetic tunnel junction layers MTJ in a plan view, but might not be arranged on the four sides. The sub-blocking pattern SBP will be described in detail with reference to FIG. 8B.

Of the plurality of magnetic tunnel junction layers MTJ, a first magnetic tunnel junction layer MTJ may be spaced apart from a second magnetic tunnel junction layer MTJ, which is adjacent to the first magnetic tunnel junction layer MTJ in a diagonal direction with respect to each of the first horizontal direction (X direction) and the second horizontal direction (Y direction), by a first distance SD1, and may be spaced apart from a third magnetic tunnel junction layer MTJ, which is adjacent to the first magnetic tunnel junction layer MTJ in the first horizontal direction (X direction) or the second horizontal direction (Y direction), by a second distance SD2. The second distance SD2 may be greater than the first distance SD1.

The sub-blocking pattern SBP may be arranged between a pair of magnetic tunnel junction layers MTJ, which are spaced apart from each other by the second distance SD2 in the horizontal direction, or might not be arranged between a pair of magnetic tunnel junction layers MTJ, which are spaced apart from each other by the first distance SD1 in the horizontal direction. For example, the sub-blocking pattern SBP may be arranged between a pair of magnetic tunnel junction layers MTJ, which are adjacent to each other in a diagonal direction with respect to each of the first horizontal direction (X direction) and the second horizontal direction (Y direction), and might not be arranged between a pair of magnetic tunnel junction layers MTJ, which are adjacent to each other in the first horizontal direction (X direction) or the second horizontal direction (Y direction), among the plurality of magnetic tunnel junction layers MTJ.

FIGS. 8A to 8D are cross-sectional views illustrating a method of manufacturing a variable resistance memory device according to an embodiment of the present inventive concept. FIG. 8E is a cross-sectional view illustrating a variable resistance memory device according to an embodiment of the present inventive concept. FIG. 9A and FIG. 9B are cross-sectional views illustrating part of a variable resistance memory device according to an embodiment of the present inventive concept, and FIG. 9C is a plan view illustrating part of a variable resistance memory device according to an embodiment of the present inventive concept. Specifically, FIGS. 8A to 8E are cross-sectional views taken along line A-A′ of FIG. 7A. FIG. 9A is a partial cross-sectional view taken along line B-B′ of FIG. 7A. FIG. 9B is a partial cross-sectional view taken along line C-C′ of FIG. 7A, and FIG. 9C is a plan view corresponding to the portion VIIB of FIG. 7A.

Referring to FIG. 8A, device isolation layers 102 are formed in a substrate 100 having a first region R1 and a second region R2 to form active regions 100a that are defined by the device isolation layers 102. First transistors 116 are formed in the active regions 100a of the first region R1. For example, two first gate electrodes 108 may be arranged in each of the active regions 100a to form two first transistors 116. A first source region 112 may be formed in a center or central region of each of the active regions 100a. The first source region 112 may be a common source region that is shared by the two first transistors 116 formed in each of the active regions 100a. First drain regions 114 may be formed at both edges of each of the active regions 100a.

In embodiments of the present inventive concept, the first transistor 116 may be a buried gate type transistor. The first gate electrodes 108 may be positioned in trenches 104 that are formed in the substrate 100. The first gate electrodes 108 may fill parts of lower sides of the trenches 104. First gate insulating layer patterns 106 may be interposed between the substrate 100 and the first gate electrodes 108. First hard mask patterns 110 may cover the first gate electrodes 108 and may fill parts of upper sides of the trenches 104. The first gate insulating layer patterns 106, the first gate electrodes 108, and the first hard mask patterns 110 may together be referred to as a first gate structure. In embodiments of the present inventive concept, the first transistor 116 may be a planar type transistor in which the first gate electrode 108 is formed on a top surface of the substrate 100.

Source lines 132 may be formed on the first source regions 112 of the active regions 100a, respectively. For example, the source lines 132 may contact top surfaces of the first source regions 112, respectively. For example, the source line 132 may include at least one of metals such as tungsten (W), titanium (Ti), and tantalum (Ta) and metal nitrides such as tungsten nitride (WN), titanium nitride (TiN), and tantalum nitride (TaN).

The second transistor 118 constituting core/peripheral circuits may be formed on the substrate 100 of the second region R2. In embodiments of the present inventive concept, the second transistor 118 may be a planar type transistor. For example, the second transistor 118 may include a second gate insulating layer pattern 120, a second gate electrode 122, and a second source/drain region 126 formed on the substrate 100 in the second region R2. A second hard mask pattern 124 may cover the second gate electrode 122. The second gate insulating layer pattern 120, the second gate electrode 122, and the second hard mask pattern 124 may together be referred to as a second gate structure.

In the first region R1 and the second region R2, a first interlayer insulating layer 140 may be formed on the substrate 100. The first interlayer insulating layer 140 may be formed to cover the source lines 132, the first transistors 116, and the second transistor 118 with a sufficient thickness. In embodiments of the present inventive concept, the first interlayer insulating layer 140 may include a first lower interlayer insulating layer 140a and a second lower interlayer insulating layer 140b. The source lines 132 may pass through the first lower interlayer insulating layer 140a.

In the first region R1, contact plugs 134 may penetrate the first interlayer insulating layer 140 and may contact the first drain regions 114. The contact plugs 134 may contact the first drain regions 114 and may penetrate the first lower interlayer insulating layer 140a and the second lower interlayer insulating layer 140b. Top surfaces of the contact plugs 134 may be at a vertical level higher than top surfaces of the source lines 132.

First wiring lines 142 may be provided on the contact plugs 134. A first inter-wiring insulating layer 144 may be arranged among the first wiring lines 142. For example, the first wiring lines 142 may be arranged in the first inter-wiring insulating layer 144. The first inter-wiring insulating layer 144 may surround the first wiring lines 142. For example, the first inter-wiring insulating layer 144 may include silicon oxide or an insulating material with a dielectric constant that is lower than that of silicon oxide. For example, the first inter-wiring insulating layer 144 may include a tetraethyl orthosilicate (TEOS) film, an ultra-low-K (ULK) film, or an extreme low-k (ELK) film. In embodiments of the present inventive concept, the ULK film or the ELK film may have a dielectric constant of about 2 to about 3.5. In embodiments of the present inventive concept, the first inter-wiring insulating layer 144 may include a SiOC film, a SiOF film, a SiCH film, a SiCOH film, or a combination thereof.

On the first wiring lines 142 and the first inter-wiring insulating layer 144, a second inter-wiring insulating layer 148 and first wiring contacts 146 electrically connected to the first wiring lines 142 by penetrating the second inter-wiring insulating layer 148 may be formed. The first wiring contacts 146 may be arranged on the first wiring lines 142, respectively. The first wiring contacts 146 may be electrically connected to the corresponding first wiring lines 142. In embodiments of the present inventive concept, the first wiring contacts 146 may contact the corresponding first wiring lines 142. However, embodiments of the present inventive concept are not limited thereto. For example, at least one wiring contact and at least one wiring line are interposed between each of the first wiring lines 142 and each of the first wiring contacts 146 so that each of the first wiring lines 142 and each of the first wiring contacts 146 may be electrically connected to each other through the at least one wiring contact and the at least one wiring line.

The second inter-wiring insulating layer 148 may be formed to fill spaces among the first wiring contacts 146. For example, the second inter-wiring insulating layer 148 may be formed to fill spaces that are between the first wiring contacts 146. The second inter-wiring insulating layer 148 may surround the first wiring contacts 146. For example, the second inter-wiring insulating layer 148 may include silicon oxide or an insulating material with a dielectric constant that is lower than that of silicon oxide. In embodiments of the present inventive concept, the second inter-wiring insulating layer 148 may include a TEOS film, a ULK film, or an ELK film.

After an isolation insulating layer 150 covering the first wiring contacts 146 and the second inter-wiring insulating layer 148 is formed, lower electrode contacts 158 contacting the corresponding first wiring contacts 146 by penetrating the isolation insulating layer 150 may be formed. The isolation insulating layer 150 may include a first isolation insulating layer 150a and a second isolation insulating layer 150b covering the first isolation insulating layer 150a. The first isolation insulating layer 150a may include an insulating material with a dielectric constant that is higher than that of silicon oxide and a dielectric constant that is lower than that of silicon nitride. In embodiments of the present inventive concept, the first isolation insulating layer 150a may include an insulating material other than oxide. For example, the first isolation insulating layer 150a may include SiCN. The second isolation insulating layer 150b may include an insulating material with a dielectric constant that is lower than that of the first isolation insulating layer 150a. In embodiments of the present inventive concept, the second isolation insulating layer 150b may include an insulating material that is different from that of the first isolation insulating layer 150a. For example, the second isolation insulating layer 150b may include silicon oxide. The second isolation insulating layer 150b may be formed thicker than the first isolation insulating layer 150a. For example, the first isolation insulating layer 150a may be formed to have a thickness of about 150 Å to about 250 Å, and the second isolation insulating layer 150b may be formed to have a thickness of about 300 Å to about 500 Å. The isolation insulating layer 150 may cover the first wiring contacts 146 and the second inter-wiring insulating layer 148 with a substantially constant thickness.

In the first region R1, the lower electrode contacts 158 may be arranged on the corresponding first wiring contacts 146, respectively. In embodiments of the present inventive concept, the lower electrode contacts 158 may be omitted without being formed.

A lower electrode material layer 160P, a fixed material layer 162P, a tunnel barrier material layer 164P, a free material layer 166P, and an upper electrode material layer 170P are sequentially formed on the isolation insulating layer 150 and the lower electrode contacts 158. The fixed material layer 162P, the tunnel barrier material layer 164P, and the free material layer 166P may constitute a magnetic tunnel junction stacked structure 168P.

For example, each of the lower electrode material layer 160P and the upper electrode material layer 170P may include a metal or metal nitride. For example, the fixed material layer 162P may include iron manganese (FeMn), iridium manganese (IrMn), platinum manganese (PtMn), manganese oxide (MnO), manganese sulfide (MnS), manganese tellurium (MnTe), manganese fluoride (MnF₂), iron fluoride (FeF₂), iron chloride (FeCl₂), iron oxide (FeO), cobalt chloride (CoCl₂), cobalt oxide (CoO), nickel chloride (NiCl₂), nickel oxide (NiO), or Cr. In embodiments of the present inventive concept, a lower ferromagnetic layer, an anti-ferromagnetic coupling spacer layer, and an upper ferromagnetic layer may be arranged on the fixed material layer 162P. For example, each of the upper ferromagnetic layer and the lower ferromagnetic layer may be a ferromagnetic material including at least one of Fe, Ni, and Co. For example, the anti-ferromagnetic coupling spacer layer may include at least one of Ru, iridium (Ir), and/or rhodium (Rh). For example, a tunnel barrier layer pattern 164 may include aluminum oxide or magnesium oxide. For example, a free layer pattern 166 may be a ferromagnetic material including at least one of Fe, Ni, and Co.

Referring to FIG. 8B, a blocking pattern BP are formed on the upper electrode material layer 170P. The blocking pattern BP may include a main blocking pattern MBP and a plurality of sub-blocking patterns SBP. The blocking pattern BP may include, for example, a nitride, a conductive nitride, or a combination thereof. For example, the blocking pattern BP may include silicon nitride, TiN, or a stacked structure in which silicon nitride is stacked on TiN. The blocking pattern BP may be formed to have a thickness of about hundreds of Å.

The main blocking pattern MBP may be formed to cover the second region R2. For example, the main blocking pattern MBP may be formed to cover the entire second region R2. For example, the main blocking pattern MBP may cover an entire top surface of a portion of the upper electrode material layer 170P that is arranged in the second region R2.

The plurality of sub-blocking patterns SBP may be arranged in the first region R1. The plurality of sub-blocking patterns SBP may be apart from one another in the horizontal direction and may cover top surfaces of portions of the upper electrode material layer 170P arranged in the first region R1. Each of the plurality of sub-blocking patterns SBP may have a circular planar shape as illustrated in FIG. 7B. However, embodiments of the present inventive concept are not limited thereto. For example, each of the plurality of sub-blocking patterns SBP may have a circular or elliptical planar shape, a polygonal planar shape such as a square, or a polygonal planar shape with rounded vertices, such as a square with rounded vertices or rounded corners.

As illustrated in FIG. 7B, the plurality of sub-blocking patterns SBP may be arranged between a pair of magnetic tunnel junction layers MTJ that are spaced apart from each other by a relatively large second distance SD2 in the horizontal direction, and might not be arranged between a pair of magnetic tunnel junction layers MTJ that are spaced apart from each other by a relatively small first distance SD1 in the diagonal direction.

Referring to FIGS. 8B and 8C together, after a mask pattern is formed on the upper electrode material layer 170P and the blocking pattern BP, the upper electrode material layer 170P, the free material layer 166P, the tunnel barrier material layer 164P, the fixed material layer 162P, and the lower electrode material layer 160P are patterned to form a plurality of variable resistance pattern structures 161. Each of the plurality of variable resistance pattern structures 161 may have an isolated island shape. The plurality of variable resistance pattern structures 161 may be spaced apart from one another in the horizontal direction. Bottom surfaces of the plurality of variable resistance pattern structures 161 may contact top surfaces of the lower electrode contacts 158 and top surfaces of portions of the isolation insulating layer 150 covering sidewalls of the lower electrode contacts 158. Each of the plurality of variable resistance pattern structures 161 may have a structure in which a lower electrode 160, the magnetic tunnel junction pattern 168, and an upper electrode 170 are stacked. For example, bottom surfaces of the lower electrodes 160 may contact the top surfaces of the lower electrode contacts 158 and the top surfaces of the portions of the isolation insulating layer 150 that covers the sidewalls of the lower electrode contacts 158. The magnetic tunnel junction pattern 168 may constitute a variable resistance layer and may include a fixed layer pattern 162, the tunnel barrier layer pattern 164, and the free layer pattern 166. Each of the upper electrode 170, the free layer pattern 166, the tunnel barrier layer pattern 164, the fixed layer pattern 162, and the lower electrode 160 may be part of each of the patterned upper electrode material layer 170P, the free material layer 166P, the tunnel barrier material layer 164P, the fixed material layer 162P, and the lower electrode material layer 160P.

The variable resistance pattern structure 161 may have a tapered shape of which horizontal width is reduced away from the substrate 100 in a vertical direction (Z direction). For example, each of the lower electrode 160, the magnetic tunnel junction pattern 168 including the fixed layer pattern 162, the tunnel barrier layer pattern 164, and the free layer pattern 166, and the upper electrode 170 included in the variable resistance pattern structure 161 may have a tapered shape of which horizontal width is reduced away from the substrate 100 in the vertical direction (Z direction).

Each of the lower electrode 160 and the upper electrode 170 may include a metal or metal nitride. For example, the fixed layer pattern 162 may include FeMn, IrMn, PtMn, MnO, MnS, MnTe, MnF₂, FeF₂, FeCl₂, FeO, CoCl₂, CoO, NiCl₂, NiO, or Cr.

A lower ferromagnetic layer, an anti-ferromagnetic coupling spacer layer, and an upper ferromagnetic layer may be further arranged on the fixed layer pattern 162. For example, each of the upper ferromagnetic layer and the lower ferromagnetic layer may be a ferromagnetic material including at least one of Fe, Ni, and/or Co. For example, the anti-ferromagnetic coupling spacer layer may include at least one of Ru, iridium (Ir), and/or rhodium (Rh). For example, the tunnel barrier layer pattern 164 may include aluminum oxide or magnesium oxide. For example, the free layer pattern 166 may be a ferromagnetic material including at least one of Fe, Ni, and/or Co.

The variable resistance pattern structure 161 is not limited to the above-described configuration described as an example, and various modified embodiments are possible. In embodiments of the present inventive concept, the variable resistance pattern structure 161 might not include the lower electrode 160.

In a process of forming the plurality of variable resistance pattern structures 161, the blocking pattern BP may be removed. In the process of forming the plurality of variable resistance pattern structures 161, part of the isolation insulating layer 150 may be removed. The remaining isolation insulating layer 150 may have protrusions 150C corresponding to the blocking pattern BP, and the protrusions 150C may be limited by isolation recesses 150R. The isolation recesses 150R may extend inward from a top surface of the isolation insulating layer 150, but might not extend to a bottom surface of the isolation insulating layer 150. In embodiments of the present inventive concept, the isolation recesses 150R may pass through the second isolation insulating layer 150b, but might not pass through the first isolation insulating layer 150a. In embodiments of the present inventive concept, the isolation recesses 150R may extend inward from a top surface of the second isolation insulating layer 150b, but might not extend to a bottom surface of the second isolation insulating layer 150b, that is, a top surface of the first isolation insulating layer 150a, and thus might not pass through the second isolation insulating layer 150b. In embodiments of the present inventive concept, the isolation recesses 150R may extend inward from the top surface of the first isolation insulating layer 150a through the second isolation insulating layer 150b, but might not extend to a bottom surface of the first isolation insulating layer 150a, and thus might not pass through the first isolation insulating layer 150a.

When there is no blocking pattern BP, in the process of forming the plurality of variable resistance pattern structures 161, a through recess may occur in a portion of the isolation insulating layer 150 relatively far away in the horizontal direction from the plurality of variable resistance pattern structures 161 so that the second inter-wiring insulating layer 148 may be exposed, that voids may occur in the second inter-wiring insulating layer 148, or that electrical defects such as short circuit may occur in the first wiring contacts 146 that is surrounded by the second inter-wiring insulating layer 148. However, in the process of forming the plurality of variable resistance pattern structures 161, a protrusion 150C corresponding to the blocking pattern BP is formed in the portion of the isolation insulating layer 150 relatively far away in the horizontal direction from the plurality of variable resistance pattern structures 161, and the isolation recess 150R does not completely pass through the isolation insulating layer 150.

Referring to FIG. 8D, a capping layer pattern 172 is formed on the plurality of variable resistance pattern structures 161 and the isolation insulating layer 150. The capping layer pattern 172 may be formed to conformally cover the plurality of variable resistance pattern structures 161 and the isolation insulating layer 150. The capping layer pattern 172 may be provided to protect the plurality of variable resistance pattern structures 161. The capping layer pattern 172 may include an insulating material. The capping layer pattern 172 may include, for example, silicon nitride.

Referring to FIG. 8E, a third inter-wiring insulating layer 174 covering the capping layer pattern 172 and filling spaces among the plurality of variable resistance pattern structures 161 is formed. The third inter-wiring insulating layer 174 may include, for example, silicon oxide. For example, the third inter-wiring insulating layer 174 may be silicon oxide formed by a high density plasma (HDP) process. In addition, for example, the third inter-wiring insulating layer 174 may include an insulating material with a dielectric constant that is lower than that of silicon oxide. In embodiments of the present inventive concept, the third inter-wiring insulating layer 174 may include a ULK film or an ELK film.

In the second region R2, a plurality of second wiring contacts 176 are formed to penetrate the third inter-wiring insulating layer 174, the capping layer pattern 172, and the isolation insulating layer 150 and may be connected to the plurality of first wiring contacts 146. Each of the plurality of second wiring contacts 176 may have a structure in which a barrier metal layer and a metal layer are stacked. The barrier metal layer may include, for example, Ti, titanium nitride, Ta, or tantalum nitride. The metal layer may include copper (Cu), W, or Al.

A fourth inter-wiring insulating layer 184 is formed on the third inter-wiring insulating layer 174 and the plurality of second inter-wiring contacts 176. For example, the fourth inter-wiring insulating layer 184 may include an insulating material with a dielectric constant that is lower than that of silicon oxide. In embodiments of the present inventive concept, the fourth inter-wiring insulating layer 184 may include a ULK film or an ELK film.

A plurality of bit lines 182 that is connected to the plurality of upper electrodes 170 of the plurality of variable resistance pattern structures 161 and penetrates the fourth inter-wiring insulating layer 184 and the capping layer pattern 172 in the first region R1 may be formed, and a plurality of second wiring lines 186 that is connected to the plurality of second wiring contacts 176 and penetrates the fourth inter-wiring insulating layer 184 in the second region R2 may be formed. The plurality of bit lines 182 and the plurality of second wiring lines 186 may be formed to form the variable resistance memory device VRM. Each of the plurality of bit lines 182 and the plurality of second wiring lines 186 may have a structure in which a barrier metal layer and a metal layer are stacked. The barrier metal layer may include, for example, Ti, titanium nitride, Ta, or tantalum nitride. The metal layer may include Cu, W, or Al. In embodiments of the present inventive concept, the plurality of bit lines 182 and the plurality of second wiring lines 186 may be formed together.

Referring to FIGS. 8E and 9A to 9C together, the variable resistance memory device VRM may include the substrate 100 that is divided into the first region R1 and the second region R2. The first region R1 may be a cell array region in which magnetoresistive memory cells are formed. The second region R2 may be positioned around the first region R1 and may be a peripheral circuit region in which core/peripheral circuits are formed.

In the first region R1 and the second region R2, the substrate 100 may include the active regions 100a that is defined by the device isolation layers 102. The first transistors 116 may be provided in the active regions 100a of the first region R1. For example, the two first transistors 116 including the two first gate electrodes 108 may be formed in each of the active regions 100a. The first source region 112 may be formed in the center or central region of each of the active regions 100a. The first source region 112 may be a common source region shared by the two first transistors 116 formed in each of the active regions 100a. The first drain regions 114 may be formed at both edges of each of the active regions 100a.

In embodiments of the present inventive concept, the first transistor 116 may be a buried gate type transistor. The first gate electrodes 108 may be positioned in the trenches 104 formed in the substrate 100. The first gate electrodes 108 may fill parts of lower sides of the trenches 104. The first gate insulating layer patterns 106 may be interposed between the substrate 100 and the first gate electrodes 108. The first hard mask patterns 110 may cover the first gate electrodes 108 and may fill parts of upper sides of the trenches 104. In embodiments of the present inventive concept, the first transistor 116 may be a planar type transistor in which the first gate electrode 108 is formed on the top surface of the substrate 100. The source lines 132 may be formed on the first source regions 112 of the active regions 100a, respectively. For example, the source lines 132 may contact the top surfaces of the first source regions 112, respectively.

The second transistor 118 constituting core/peripheral circuits may be formed on the substrate 100 of the second region R2. In embodiments of the present inventive concept, the second transistor 118 may be a planar type transistor. For example, the second transistor 118 may include the second gate insulating layer pattern 120, the second gate electrode 122, and the second source/drain region 126 formed on the substrate 100 in the second region R2. The second hard mask pattern 124 may cover the second gate electrode 122.

In the first region R1 and the second region R2, the first interlayer insulating layer 140 may be formed on the substrate 100. The first interlayer insulating layer 140 may be formed to cover the source lines 132, the first transistors 116, and the second transistor 118 with a sufficient thickness. In embodiments of the present inventive concept, the first interlayer insulating layer 140 may include the first lower interlayer insulating layer 140a and the second lower interlayer insulating layer 140b. The source lines 132 may pass through the first lower interlayer insulating layer 140a.

In the first region R1, the contact plugs 134 may be formed to penetrate the first interlayer insulating layer 140 and may contact the first drain regions 114. The contact plugs 134 may contact the first drain regions 114 by penetrating the first lower interlayer insulating layer 140a and the second lower interlayer insulating layer 140b. The top surfaces of the contact plugs 134 may be at a vertical level that is higher than the top surfaces of the source lines 132.

The first wiring lines 142 may be provided on the contact plugs 134. The first inter-wiring insulating layer 144 may be arranged among the first wiring lines 142. The first inter-wiring insulating layer 144 may at least partially surround the first wiring lines 142.

The first wiring contacts 146 may be arranged on the first wiring lines 142. The first wiring contacts 146 may be electrically connected to the corresponding first wiring lines 142. In embodiments of the present inventive concept, the first wiring contacts 146 may contact the corresponding first wiring lines 142. However, embodiments of the present inventive concept are not limited thereto. For example, at least one wiring contact and at least one wiring line may be interposed between each of the first wiring lines 142 and each of the first wiring contacts 146 so that each of the first wiring lines 142 and each of the first wiring contacts 146 may be electrically connected to each other through the at least one wiring contact and the at least one wiring line. The second inter-wiring insulating layer 148 may be arranged among the first wiring contacts 146. The second inter-wiring insulating layer 148 may at least partially surround the first wiring contacts 146.

The isolation insulating layer 150 may cover the first wiring contacts 146 and the second inter-wiring insulating layer 148. The isolation insulating layer 150 may include the first isolation insulating layer 150a and the second isolation insulating layer 150b covering the first isolation insulating layer 150a. In embodiments of the present inventive concept, the maximum thickness of the second isolation insulating layer 150b may be greater than the maximum thickness of the first isolation insulating layer 150a.

In the first region R1, the lower electrode contacts 158 may be arranged on the corresponding first wiring contacts 146, respectively. The lower electrode contacts 158 may contact the corresponding first wiring contacts 146 by penetrating the isolation insulating layer 150. The lower electrode contacts 158 may be arranged when direct contact between the first wiring contacts 146 and the plurality of variable resistance pattern structures 161 is difficult.

In the first region R1, the isolation insulating layer 150 may cover the sidewalls of the lower electrode contacts 158. In the first region R1, the plurality of variable resistance pattern structures 161 constituting a memory cell may be provided on the lower electrode contacts 158. Each of the plurality of variable resistance pattern structures 161 may have an isolated island shape. The plurality of variable resistance pattern structures 161 may be spaced apart from one another in the horizontal direction. The bottom surfaces of the plurality of variable resistance pattern structures 161 may contact the top surfaces of the lower electrode contacts 158 and the top surfaces of the portions of the isolation insulating layer 150 covering the sidewalls of the lower electrode contacts 158. Each of the plurality of variable resistance pattern structures 161 may have a structure in which the lower electrode 160, the magnetic tunnel junction pattern 168, and the upper electrode 170 are stacked. For example, the bottom surfaces of the lower electrodes 160 may contact the top surfaces of the lower electrode contacts 158 and the top surfaces of the portions of the isolation insulating layer 150 covering the sidewalls of the lower electrode contacts 158.

The magnetic tunnel junction pattern 168 may constitute a variable resistance layer and may include the fixed layer pattern 162, the tunnel barrier layer pattern 164, and the free layer pattern 166. The variable resistance pattern structure 161 may have a tapered shape of which horizontal width is reduced away from the substrate 100 in the vertical direction (Z direction). For example, each of the lower electrode 160, the magnetic tunnel junction pattern 168 including the fixed layer pattern 162, the tunnel barrier layer pattern 164, and the free layer pattern 166, and the upper electrode 170 included in the variable resistance pattern structure 161 may have a tapered shape of which horizontal width is reduced away from the substrate 100 in the vertical direction (Z direction). A lower ferromagnetic layer, an anti-ferromagnetic coupling spacer layer, and an upper ferromagnetic layer may be further arranged on the fixed layer pattern 162. The variable resistance pattern structure 161 is not limited to the above-described configuration described as an example, and various modified embodiments are possible. In embodiments of the present inventive concept, the variable resistance pattern structure 161 may not include the lower electrode 160.

The capping layer pattern 172 may cover the plurality of variable resistance pattern structures 161 and the isolation insulating layer 150. The third inter-wiring insulating layer 174 may cover the capping layer pattern 172 and may fill spaces among the plurality of variable resistance pattern structures 161. For example, the third inter-wiring insulating layer 174 may be disposed between variable resistance pattern structures 161. The plurality of second wiring contacts 176 may be electrically connected to the plurality of first wiring contacts 146 by penetrating the third inter-wiring insulating layer 174, the capping layer pattern 172, and the isolation insulating layer 150 in the second region R2. The fourth inter-wiring insulating layer 184 may cover the third inter-wiring insulating layer 174 and the plurality of second wiring contacts 176. The plurality of bit lines 182 may be electrically connected to the plurality of upper electrodes 170 of the plurality of variable resistance pattern structures 161 by penetrating the fourth inter-wiring insulating layer 184 and the capping layer pattern 172 in the first region R1. The plurality of second wiring lines 186 may be electrically connected to the plurality of second wiring contacts 176 by penetrating the fourth inter-wiring insulating layer 184 in the second region R2.

The isolation insulating layer 150 may have the protrusions 150C that are defined by the isolation recesses 150R. The isolation recesses 150R may extend inward from the top surface of the isolation insulating layer 150, but might not extend to the bottom surface of the isolation insulating layer 150. Bottom surfaces of the isolation recesses 150R may be at a vertical level that is lower than top surfaces of the protrusions 150C and higher than the bottom surface of the isolation insulating layer 150. The bottom surfaces of the isolation recesses 150R may be at a first vertical level LV1, and the top surfaces of the protrusions 150C may be at a second vertical level LV2 that is higher than the first vertical level LV1. The first vertical level LV1 may be the same as a vertical level of the bottom surface of the second isolation insulating layer 150b and a vertical level of the top surface of the first isolation insulating layer 150a. However, embodiments of the present inventive concept are not limited thereto. For example, the first vertical level LV1 may be lower than the vertical level of the top surface of the second isolation insulating layer 150b and higher than the vertical level of the bottom surface of the second isolation insulating layer 150b. For example, the first vertical level LV1 may be lower than the vertical level of the top surface of the first isolation insulating layer 150a and higher than the vertical level of the bottom surface of the first isolation insulating layer 150a.

A first surface of the isolation insulating layer 150 in the isolation recess 150R may extend from the bottom surface of the isolation recess 150R toward the variable resistance pattern structure 161 with a first angle θ1 with respect to the substrate 100, and a second surface of the isolation insulating layer 150 may extend from the bottom surface of the isolation recess 150R toward the protrusion 150C with a second angle θ2, which is greater than the first angle θ1, with respect to the substrate 100. For example, each of the first angle θ1 and the second angle θ2 has an acute angle.

In a plan view, four adjacent variable resistance pattern structures 161 among the plurality of variable resistance pattern structures 161 may be arranged at four vertices of a square. For example, each of four sides of the square, in which the four adjacent variable resistance pattern structures 161 among the plurality of variable resistance pattern structures 161 are arranged at the four vertices in a plan view, may extend in a diagonal direction with respect to each of the first horizontal direction (X direction) and the second horizontal direction (Y direction).

In a plan view, the protrusion 150C may be positioned at the center or central region of the square in which the four adjacent variable resistance pattern structures 161 among the plurality of variable resistance pattern structures 161 are arranged at the four vertices, but might not be positioned at the four sides of the square. For example, in a plan view, the protrusion 150C may be positioned at a portion in which two diagonal lines of the square, in which the four adjacent variable resistance pattern structures 161 among the plurality of variable resistance pattern structures 161 are arranged at the four vertices, intersect with each other.

The protrusion 150C might not be arranged between a pair of variable resistance pattern structures 161 that are spaced apart from each other by a first distance SD1 in the diagonal direction among the plurality of variable resistance pattern structures 161. For example, the protrusion 150C might not be arranged between a pair of variable resistance pattern structures 161, which are adjacent to each other in a diagonal direction with respect to each of the first horizontal direction (X direction) and the second horizontal direction (Y direction). The protrusion 150Ca may be arranged between a pair of variable resistance pattern structures 161, which are spaced apart from each other by a second distance SD2 in the horizontal direction. For example, the protrusion 150Ca may be arranged between a pair of variable resistance pattern structures 161, which are adjacent to each other in the first horizontal direction (X direction) or the second horizontal direction (Y direction). The lowermost end of the top surface of the isolation insulating layer 150 excluding where the protrusion 150C and the portion in which the isolation recess 150R, which defines the protrusion 150C, are positioned may be at a third vertical level LV3 equal to or higher than the second vertical level LV2. A vertical level of an uppermost end of the isolation insulating layer 150 may be higher than the second vertical level LV2 and the third vertical level LV3. The uppermost end of the isolation insulating layer 150, the top surfaces of the lower electrode contacts 158, and the bottom surfaces of the plurality of variable resistance pattern structures 161 may be at the same vertical level as each other. For example, the uppermost end of the isolation insulating layer 150 and the bottom surfaces of the lower electrodes 160 may be at the same vertical level as each other.

In a plan view, the isolation recesses 150R may at least partially surround the protrusions 150C. In a plan view, the isolation recesses 150R may be spaced apart from the plurality of variable resistance pattern structures 161. The isolation recess 150R may have a first width W1 in a direction between the pair of variable resistance pattern structures 161 that are spaced apart from each other by the second distance SD2 in the horizontal direction, and may have a second width W2, which is greater than the first width W1, in a direction between the pair of variable resistance pattern structures 161 that are spaced apart from each other by the first distance SD1 in the diagonal direction.

In a plan view, the isolation recess 150R may have the first width W1 in a diagonal direction of the square (e.g., with respect to two adjacent sides of the square), in which the four adjacent variable resistance pattern structures 161 among the plurality of variable resistance pattern structures 161 are arranged at the four vertices, and may have the second width W2 greater than the first width W1 in a direction in which the four sides of the square extend. For example, the isolation recess 150R may have the first width W1 in the first horizontal direction (X direction) or the second horizontal direction (Y direction), and may have the second width W2 greater than the first width W1 in a diagonal direction with respect to each of the first horizontal direction (X direction) and the second horizontal direction (Y direction).

In the variable resistance memory device VRM according to an embodiment of the present inventive concept, because the protrusion 150C is arranged between the pair of variable resistance pattern structures 161 that are spaced apart from each other by the relatively large second distance SD2 in the horizontal direction among the plurality of variable resistance pattern structures 161, the isolation recess 150R does not pass through the isolation insulating layer 150 so that it is possible to prevent voids from occurring in the second inter-wiring insulating layer 148 or electrical defects such as short circuit from occurring in the first wiring contacts 146 that are surrounded by the second inter-wiring insulating layer 148 and to secure structural reliability and electrical reliability.

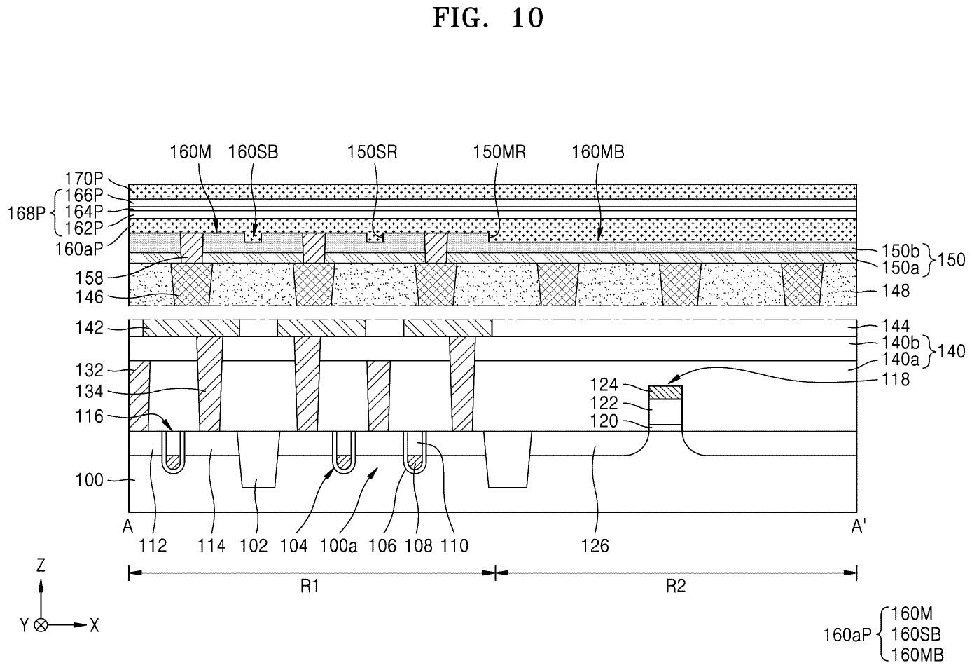

FIGS. 10 to 12 are cross-sectional views illustrating a method of manufacturing a variable resistance memory device according to an embodiment of the present inventive concept. Specifically, each of FIGS. 10 to 12 is a cross-sectional view taken along line A-A′ of FIG. 7.

Referring to FIG. 10, after the isolation insulating layer 150 illustrated in FIG. 8A is formed, parts of the isolation insulating layer 150 are removed to form a main recess 150MR and a plurality of sub-recesses 150SR. Each of the main recess 150MR and the plurality of sub-recesses 150SR may be formed to have a depth of about 80 Å to about 150 Å. Each of the main recess 150MR and the plurality of sub-recesses 150SR may be formed by removing part of an upper side of the second isolation insulating layer 150b. For example, the first isolation insulating layer 150a might not be exposed, and part of the second isolation insulating layer 150b may be exposed to a bottom surface of each of the main recess 150MR and the plurality of sub-recesses 150SR.

The main recess 150MR may be formed throughout the second region R2. For example, the main recess 150MR may be formed by removing part of an upper side of a portion of the isolation insulating layer 150 that is arranged in the second region R2.

The plurality of sub-recesses 150SR may be formed in the first region R1. The plurality of sub-recesses 150SR that are spaced apart from one another in the horizontal direction, and may be formed by removing parts of upper sides of the isolation insulating layer 150 that are arranged in the first region R1. Each of the plurality of sub-recesses 150SR may have a circular planar shape as illustrated in FIG. 7B. However, embodiments of the present inventive concept are not limited thereto. For example, each of the plurality of sub-recesses 150SR may have a circular or elliptical planar shape, a polygonal planar shape such as a square, or a polygonal planar shape with rounded vertices, such as a square with rounded vertices.

A lower electrode material layer 160aP filling the main recess 150MR and the plurality of sub-recesses 150SR is formed on the isolation insulating layer 150 and the lower electrode contacts 158. The lower electrode material layer 160aP may include a main blocking unit 160MB, which fills the main recess 150MR, and a plurality of sub-blocking units 160SB, which fill the plurality of sub-recesses 150SR. Each of the main blocking unit 160MB, which fills the main recess 150MR, and the plurality of sub-blocking units 160SB, which fill the plurality of sub-recesses 150SR, may be formed to have a thickness of about 80 Å to about 150 Å.

Thereafter, referring to FIGS. 8A to 8E, the variable resistance memory device VRM illustrated in FIGS. 8E and 9A to 9C is formed. The main blocking unit 160MB, which fills the main recess 150MR, and the plurality of sub-blocking units 160SB, which fill the plurality of sub-recesses 150SR, may perform functions of the main blocking pattern MBP and the plurality of sub-blocking patterns SBP illustrated in FIG. 8B to form the plurality of protrusions 150C and the plurality of isolation recesses 150R defining the plurality of protrusions 150C.

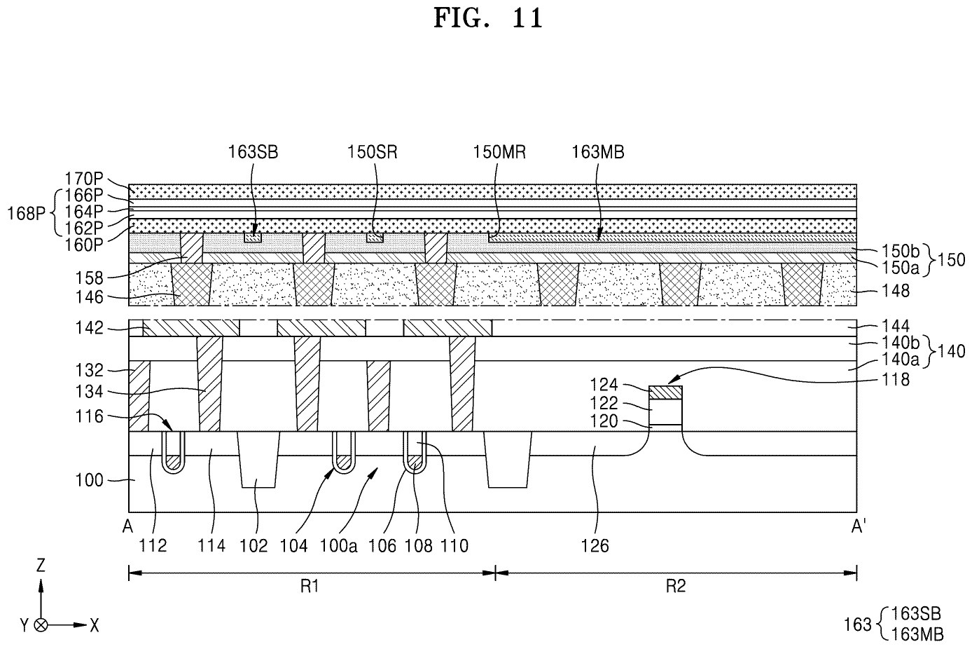

Referring to FIG. 11, after the isolation insulating layer 150 illustrated in FIG. 8A is formed, parts of the isolation insulating layer 150 are removed to form the main recess 150MR and the plurality of sub-recesses 150SR. A main blocking pattern 163MB filling the main recess 150MR and a plurality of sub-blocking patterns 163SB filling the plurality of sub-recesses 150SR are formed. Thereafter, the lower electrode material layer 160P covering the isolation insulating layer 150, the main blocking pattern 163MB, and the plurality of sub-blocking patterns 163SB is formed.

The main blocking pattern 163MB and the plurality of sub-blocking patterns 163SB may include a metal or metal nitride. In embodiments of the present inventive concept, the main blocking pattern 163MB and the plurality of sub-blocking patterns 163SB may include the same material as that of the lower electrode material layer 160P. In embodiments of the present inventive concept, the main blocking pattern 163MB and the plurality of sub-blocking patterns 163SB may include a material different from that of the lower electrode material layer 160P.

Thereafter, referring to FIGS. 8A to 8E, the variable resistance memory device VRM illustrated in FIGS. 8E and 9A to 9C is formed. The main blocking unit 160MB and the plurality of sub-blocking units 160SB may perform the functions of the main blocking pattern MBP and the plurality of sub-blocking patterns SBP illustrated in FIG. 8B to form the plurality of protrusions 150C and the plurality of isolation recesses 150R defining the plurality of protrusions 150C.

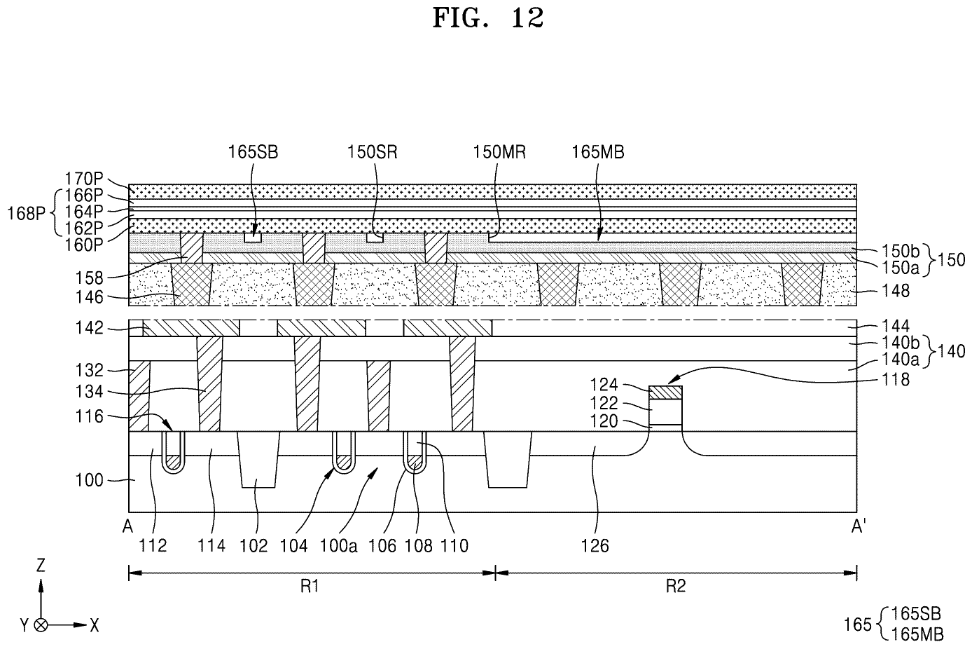

Referring to FIG. 12, after the isolation insulating layer 150 illustrated in FIG. 8A is formed, parts of the isolation insulating layer 150 are removed to form the main recess 150MR and the plurality of sub-recesses 150SR. A main blocking pattern 165MB, which fills the main recess 150MR, and a plurality of sub-blocking patterns 165SB, which fills the plurality of sub-recesses 150SR, are formed. Thereafter, the lower electrode material layer 160P covering the isolation insulating layer 150, the main blocking pattern 165MB, and the plurality of sub-blocking patterns 165SB is formed.

The main blocking pattern 165MB and the plurality of sub-blocking patterns 165SB may include an insulating material. For example, each of the main blocking pattern 163MB and the plurality of sub-blocking patterns 163SB may include silicon nitride.

Thereafter, referring to FIGS. 8A to 8E, the variable resistance memory device VRM illustrated in FIGS. 8E and 9A to 9C is formed. The main blocking pattern 165MB and the plurality of sub-blocking patterns 165SB may perform the functions of the main blocking pattern MBP and the plurality of sub-blocking patterns SBP illustrated in FIG. 8B to form the plurality of protrusions 150C and the plurality of isolation recesses 150R defining the plurality of protrusions 150C.

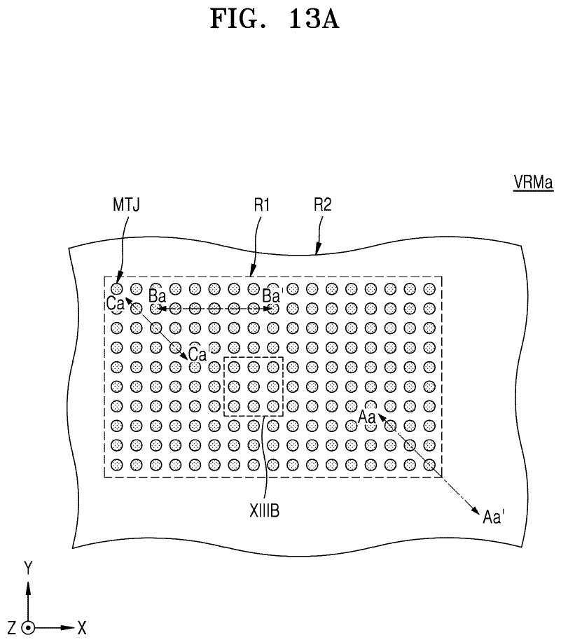

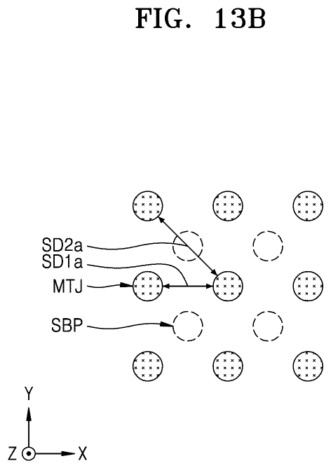

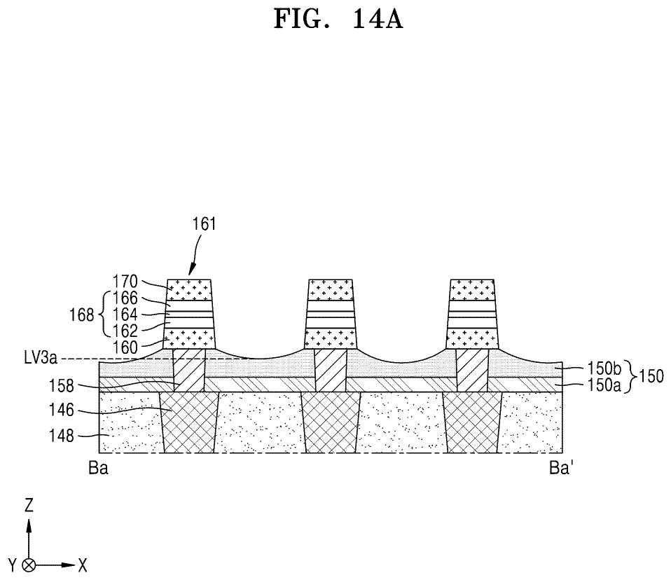

FIGS. 13A and 13B are plan views illustrating a variable resistance memory device VRMa according to an embodiment of the present inventive concept. Specifically, FIG. 13B is a plan view illustrating an arrangement of some components of the portion XIIIB of FIG. 13A.

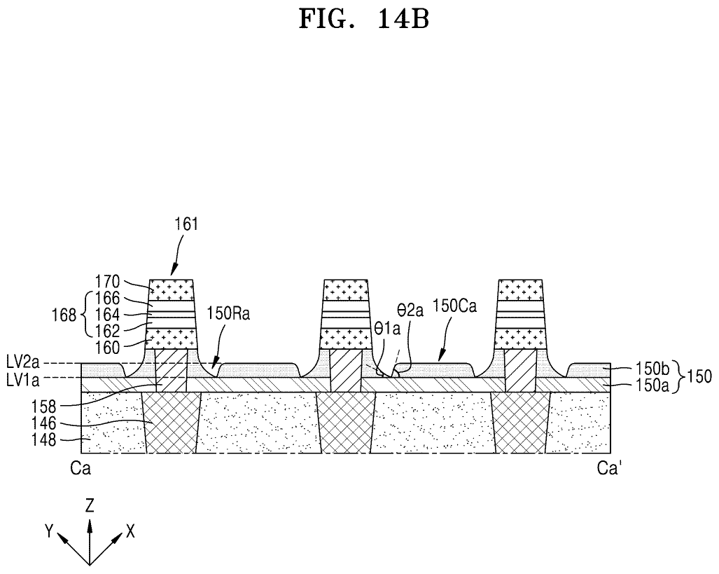

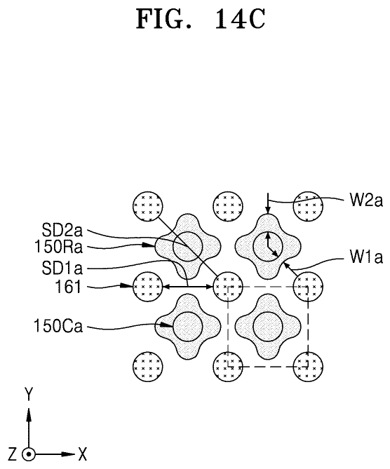

Referring to FIGS. 13A and 13B together, the variable resistance memory device VRMa may be a magnetoresistive memory device. The variable resistance memory device VRM may include a first region R1 and a second region R2 that is adjacent to the first region R1. In embodiments of the present inventive concept, in a plan view, the second region R2 may completely surround the first region R1. A plurality of magnetic tunnel junction layers MTJ may be arranged in the first region R1. The plurality of magnetic tunnel junction layers MTJ may be arranged to form a matrix. The magnetic tunnel junction layer MTJ may include a variable resistance layer. For example, the magnetic tunnel junction layer MTJ may include the magnetic tunnel junction layers MTJ11 to MTJmn, MTJ, MTJ-1, MTJ-2, MTJ-3, MTJ-4, and MTJ-5, or the magnetic tunnel junction pattern 168 illustrated in each of FIGS. 14A and 14B.

In a plan view, four adjacent magnetic tunnel junction layers MTJ among the plurality of magnetic tunnel junction layers MTJ may be arranged at four vertices of a square. For example, each of four sides of the square, in which the four adjacent magnetic tunnel junction layers MTJ are arranged at the four vertices in a plan view, may extend in a diagonal direction with respect to each of the first horizontal direction (X direction) and the second horizontal direction (Y direction). In a process of forming the variable resistance memory device VRMa, the sub-blocking pattern SBP illustrated in FIG. 8B may be arranged in the center or central region of the square that is formed by the four adjacent magnetic tunnel junction layers MTJ in a plan view, but might not be positioned on the four sides.

Of the plurality of magnetic tunnel junction layers MTJ, a first magnetic tunnel junction layer MTJ may be spaced apart from a second magnetic tunnel junction layer MTJ, which is adjacent to the first magnetic tunnel junction layer MTJ in the first horizontal direction (X direction) or the second horizontal direction (Y direction), by a first distance SD1a, and may be spaced apart from a third magnetic tunnel junction layer MTJ, which is adjacent to the first magnetic tunnel junction layer MTJ in a diagonal direction with respect to each of the first horizontal direction (X direction) and the second horizontal direction (Y direction), by a second distance SD2a. The second distance SD2a may be greater than the first distance SD1a.

The sub-blocking pattern SBP may be arranged between a pair of magnetic tunnel junction layers MTJ, which are spaced apart from each other by a relatively large second distance SD2a in the horizontal direction, or might not be arranged between a pair of magnetic tunnel junction layers MTJ, which are spaced apart from each other by a relatively small first distance SD1a in the horizontal direction. For example, the sub-blocking pattern SBP may be arranged between a pair of magnetic tunnel junction layers MTJ, which are adjacent to each other in the first horizontal direction (X direction) or the second horizontal direction (Y direction), and might not be arranged between a pair of magnetic tunnel junction layers MTJ, which are adjacent to each other in a diagonal direction with respect to each of the first horizontal direction (X direction) and the second horizontal direction (Y direction), among the plurality of magnetic tunnel junction layers MTJ.

FIGS. 14A and 14B are cross-sectional views illustrating part of a variable resistance memory device according to an embodiment of the present inventive concept, and FIG. 14C is a plan view illustrating part of a variable resistance memory device according to an embodiment of the present inventive concept. Specifically, FIG. 14A is a partial cross-sectional view taken along line Ba-Ba′ of FIG. 13A. FIG. 14B is a partial cross-sectional view taken along line Ca-Ca′ of FIG. 13A, and FIG. 14C is a plan view corresponding to the portion XIIIB of FIG. 13A. Because the cross-sectional view taken along line Aa-Aa′ of FIG. 13A is similar to FIG. 8E except for a cutting direction, separate illustrations are omitted and redundant descriptions are omitted or briefly discussed.

Referring to FIGS. 14A to 14C together, the isolation insulating layer 150 may have protrusions 150Ca that are defined by isolation recesses 150Ra. The isolation recesses 150Ra may extend inward from the top surface of the isolation insulating layer 150, but might not extend to the bottom surface of the isolation insulating layer 150. The bottom surfaces of the isolation recesses 150Ra may be at a first vertical level LV1a, and the top surfaces of the protrusions 150Ca may be at a second vertical level LV2a that is higher than the first vertical level LV1a. The first vertical level LV1a may be the same as a vertical level of the bottom surface of the second isolation insulating layer 150b and a vertical level of the top surface of the first isolation insulating layer 150a. However, embodiments of the present inventive concept are not limited thereto. For example, the first vertical level LV1a may be lower than the vertical level of the top surface of the second isolation insulating layer 150b and higher than the vertical level of the bottom surface of the second isolation insulating layer 150b. For example, the first vertical level LV1a may be lower than the vertical level of the top surface of the first isolation insulating layer 150a and higher than the vertical level of the bottom surface of the first isolation insulating layer 150a.

A first surface of the isolation insulating layer 150 in the isolation recess 150Ra may extend from a bottom surface of the isolation recess 150Ra toward the variable resistance pattern structure 161 with a first angle θ1a with respect to the substrate 100, and a second surface of the isolation insulating layer 150 may extend from the bottom surface of the isolation recess 150Ra toward the protrusion 150Ca with a second angle θ2a, which is greater than the first angle θ1a, with respect to the substrate 100. For example, each of the first angle θ1a and the second angle θ2a has an acute angle.

In a plan view, four adjacent variable resistance pattern structures 161 among the plurality of variable resistance pattern structures 161 may be arranged at four vertices of a square. For example, each of the four sides of the square, in which the four adjacent variable resistance pattern structures 161 among the plurality of variable resistance pattern structures 161 are arranged at the four vertices in a plan view, may extend in the first horizontal direction (X direction) or the second horizontal direction (Y direction).

In a plan view, the protrusion 150Ca may be positioned at the center or central region of the square in which the four adjacent variable resistance pattern structures 161 among the plurality of variable resistance pattern structures 161 are arranged at the four vertices, but might not be positioned at the four sides of the square. For example, in a plan view, the protrusion 150Ca may be positioned at a portion in which two diagonal lines of the square, in which the four adjacent variable resistance pattern structures 161 among the plurality of variable resistance pattern structures 161 are arranged at the four vertices, intersect with each other.

The protrusion 150Ca might not be arranged between a pair of variable resistance pattern structures 161, which are spaced apart from each other by a first distance SD1a in the horizontal direction, among the plurality of variable resistance pattern structures 161. For example, the protrusion 150Ca might not be arranged between a pair of variable resistance pattern structures 161 that are adjacent to each other in the first horizontal direction (X direction) or the second horizontal direction (Y direction). The protrusion 150Ca may be arranged between a pair of variable resistance pattern structures 161, which are spaced apart from each other by a second distance SD2a in the diagonal direction. For example, the protrusion 150Ca may be arranged between a pair of variable resistance pattern structures 161, which are adjacent to each other in a diagonal direction with respect to each of the first horizontal direction (X direction) and the second horizontal direction (Y direction). The lowermost end of the top surface of the isolation insulating layer 150 excluding where the protrusion 150Ca and the portion in which the isolation recess 150Ra, which defines the protrusion 150Ca, are positioned may be at a third vertical level LV3a equal to or higher than the second vertical level LV2a. A vertical level of the uppermost end of the isolation insulating layer 150 may be higher than the second vertical level LV2a and the third vertical level LV3a. The uppermost end of the isolation insulating layer 150, the top surfaces of the lower electrode contacts 158, and the bottom surfaces of the plurality of variable resistance pattern structures 161 may be at the same vertical level as each other. For example, the uppermost end of the isolation insulating layer 150 and the bottom surfaces of the lower electrodes 160 may be at the same vertical level as each other.

In a plan view, the isolation recesses 150Ra may at least partially surround the protrusions 150Ca. In a plan view, the isolation recesses 150Ra may be spaced apart from the plurality of variable resistance pattern structures 161. The isolation recess 150Ra may have a first width W1a in a direction between the pair of variable resistance pattern structures 161 that are spaced apart from each other by the second distance SD2a in the diagonal direction, and may have a second width W2a, which is greater than the first width W1a, in a direction between the pair of variable resistance pattern structures 161 that are spaced apart from each other by the first distance SD1a in the horizontal direction.

In a plan view, the isolation recess 150Ra may have the first width W1a in a diagonal direction of the square (e.g., with respect to two adjacent sides of the square), in which the four adjacent variable resistance pattern structures 161 among the plurality of variable resistance pattern structures 161 are arranged at the four vertices, and may have the second width W2a greater than the first width W1a in a direction in which the four sides of the square extend. For example, the isolation recess 150Ra may have the first width W1a in a diagonal direction with respect to each of the first horizontal direction (X direction) and the second horizontal direction (Y direction), and may have the second width W2a greater than the first width W1a in the first horizontal direction (X direction) or the second horizontal direction (Y direction).

In the variable resistance memory device VRMa according to an embodiment of the present inventive concept, because the protrusion 150Ca is arranged between the pair of variable resistance pattern structures 161 that are apart from each other by the relatively large second distance SD2a in the horizontal direction among the plurality of variable resistance pattern structures 161, the isolation recess 150Ra does not pass through the isolation insulating layer 150 so that it is possible to prevent voids from occurring in the second inter-wiring insulating layer 148 or electrical defects such as short circuit from occurring in the first wiring contacts 146 that are surrounded by the second inter-wiring insulating layer 148 and to secure structural reliability and electrical reliability.

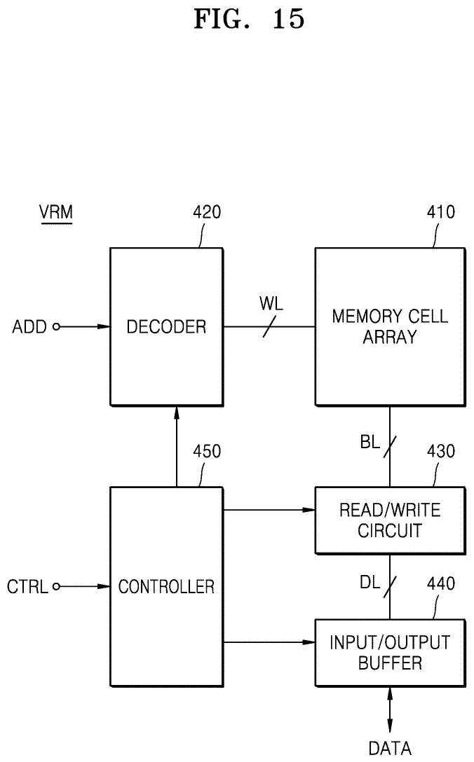

FIG. 15 is a block diagram of the variable resistance memory device VRM according to an embodiment of the present inventive concept.

Referring to FIG. 15, the variable resistance memory device VRM according to an embodiment of the present inventive concept includes a memory cell array 410, a decoder 420, a read/write circuit 430, an input/output buffer 440, and a controller 450. The memory cell array 410 may correspond to the magnetoresistive memory cell array 80 illustrated in FIG. 1 and the first region R1 illustrated in FIGS. 7A, 8A to FIG. 8E, 10, 11, 12, and 13A.

A plurality of memory cells in the memory cell array 410 are connected to the decoder 420 through the plurality of word lines WL and are connected to the read/write circuit 430 through the plurality of bit lines BL. The decoder 420 receives an external address ADD and decodes a row address and a column address to be accessed in the memory cell array 410 under the control of the controller 450 that operates according to a control signal CTRL.

The read/write circuit 430 receives data DATA from the input/output buffer 440 through a data line DL, writes the data DATA in a selected memory cell of the memory cell array 410 under the control of the controller 450, and/or provides data read from a selected memory cell of the memory cell array 410 to the input/output buffer 440 under the control of the controller 450. The memory cell may include the variable resistance pattern structure 161 illustrated in FIGS. 8E, 9A to 9C, and 14A to 14C.

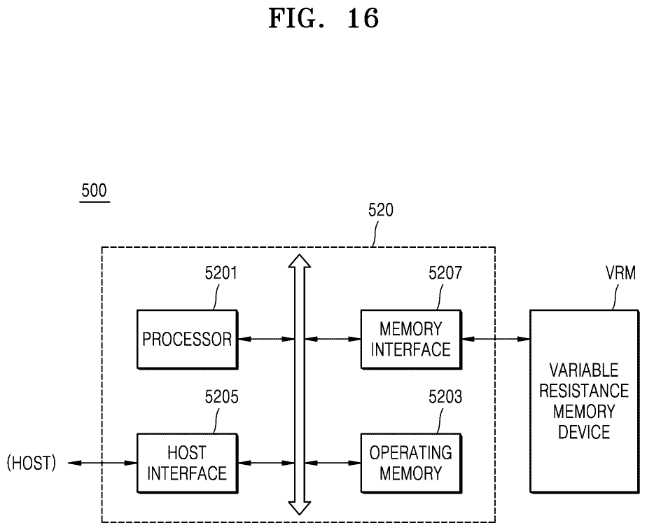

FIG. 16 is a block diagram of a data processing system 500 including the variable resistance memory device VRM according to an embodiment of the present inventive concept.

Referring to FIG. 16, the data processing system 500 may include a memory controller 520 connected between a host and the variable resistance memory device VRM. The memory controller 520 may be configured to access the variable resistance memory device VRM in response to a request from the host. The memory controller 520 may include a processor 5201, operating memory 5203, a host interface 5205, and a memory interface 5207.

The processor 5201 controls an overall operation of the memory controller 520, and the operating memory 5203 may store applications, data, and control signals for operation of the memory controller 520. The host interface 5205 performs protocol conversion for data/control signal exchange between the host and the memory controller 520.

The memory interface 5207 performs protocol conversion for data/control signal exchange between the memory controller 520 and the variable resistance memory device VRM. Because the variable resistance memory device VRM is the same as described above, description thereof is omitted. The data processing system 500 according to an embodiment of the present inventive concept may be a memory card. However, the present inventive concept is not limited thereto.

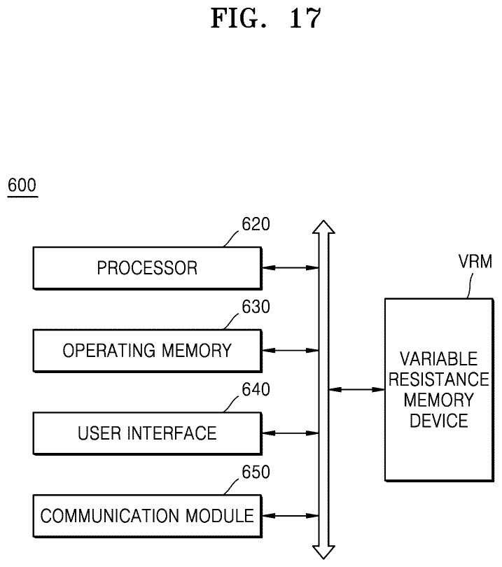

FIG. 17 is a block diagram of a data processing system 600 including the variable resistance memory device VRM according to an embodiment of the present inventive concept.

Referring to FIG. 17, the data processing system 600 includes the variable resistance memory device VRM, a processor 620, operating memory 630, and a user interface 640, and may further include a communication module 650 if necessary. The processor 620 may be a central processing unit (CPU).

The operating memory 630 stores application programs, data, and control signals for the operation of the data processing system 600. The user interface 640 provides an environment in which a user may access the data processing system 600 and provides a data processing process and results of the data processing system 600 to the user.

Because the variable resistance memory device VRM is substantially the same as the variable resistance memory devices VRM and VRMa described with reference to FIGS. 1 to 16, description thereof will be omitted. The data processing system 600 may be used as a disk device, as an internal/external memory card of a portable electronic device, or as an image processor and other application chipsets.

While the present inventive concept has been described with reference to embodiments thereof, it will be understood by those of ordinary skill in the art that various changes in form and details may be made thereto without departing from the spirit and scope of the present inventive concept.

What is claimed is:

1. A variable resistance memory device comprising:
a substrate;
a plurality of wiring contacts arranged on the substrate;
an isolation insulating layer disposed on the plurality of wiring contacts; and
a plurality of variable resistance pattern structures arranged on the isolation insulating layer, wherein the plurality of variable resistance pattern structures constitute a plurality of memory cells, and are spaced apart from one another in a horizontal direction, wherein the isolation insulating layer comprises a protrusion that is defined by an isolation recess, and
wherein four adjacent variable resistance pattern structures among the plurality of variable resistance pattern structures are respectively arranged at four vertices of a square, and the protrusion is arranged in a central region of the square.

2. The variable resistance memory device of claim 1, wherein a bottom surface of the isolation recess is at a vertical level that is lower than a top surface of the protrusion and higher than a bottom surface of the isolation insulating layer.

3. The variable resistance memory device of claim 2, wherein a horizontal width of the isolation recess in a diagonal direction of the square is less than a horizontal width of the isolation recess in a direction in which a side of four sides of the square extend.

4. The variable resistance memory device of claim 2, wherein an uppermost end of the isolation insulating layer and bottom surfaces of the plurality of variable resistance pattern structures are at a substantially same vertical level as each other, and are at a higher vertical level than the top surface of the protrusion.

5. The variable resistance memory device of claim 4, further comprising a plurality of lower electrode contacts connected to the plurality of wiring contacts, wherein the isolation insulating layer covers side surfaces of the plurality of lower electrode contacts, and
wherein the bottom surfaces of the plurality of variable resistance pattern structures contact top surfaces of the plurality of lower electrode contacts and top surfaces of portions of the isolation insulating layer that covers side surfaces of the plurality of lower electrode contacts.

6. The variable resistance memory device of claim 1, wherein the protrusion is not arranged on four sides of the square.

7. The variable resistance memory device of claim 1, wherein a first surface of the isolation insulating layer in the isolation recess extends from a bottom surface of the isolation recess toward the variable resistance pattern structure with a first angle with respect to the substrate, and a second surface of the isolation insulating layer extends from a bottom surface of the isolation recess toward the protrusion with a second angle, which is greater than the first angle, with respect to the substrate.

8. The variable resistance memory device of claim 1, wherein the isolation insulating layer comprises a first isolation insulating layer and a second isolation insulating layer covering the first isolation insulating layer, and
wherein the isolation recess passes through the second isolation insulating layer, but does not pass through the first isolation insulating layer.

9. The variable resistance memory device of claim 8, wherein the second isolation insulating layer comprises an insulating material with a dielectric constant that is lower than that of the first isolation insulating layer.

10. The variable resistance memory device of claim 8, wherein a maximum thickness of the second isolation insulating layer is greater than a maximum thickness of the first isolation insulating layer.

11. A variable resistance memory device comprising:
a substrate;
a plurality of lower electrode contacts arranged on the substrate;
an isolation insulating layer covering sidewalls of the plurality of lower electrode contacts; and
a plurality of variable resistance pattern structures spaced apart from one another in a horizontal direction on the isolation insulating layer to form a plurality of memory cells, and connected to the plurality of lower electrode contacts, wherein the isolation insulating layer comprises a protrusion that is defined by an isolation recess, wherein, among the plurality of variable resistance pattern structures, a first variable resistance pattern structure is spaced apart from a second variable resistance pattern structure by a first distance and is spaced apart from a third variable resistance pattern structure by a second distance that is greater than the first distance in a direction that is different than a direction in which the first distance extends, and
wherein the protrusion is not arranged between the first variable resistance pattern structure and the second variable resistance pattern structure, and is arranged between the first variable resistance pattern structure and the third variable resistance pattern structure.

12. The variable resistance memory device of claim 11, wherein the plurality of variable resistance pattern structures are arranged in a row in a first horizontal direction and are arranged in zigzags in a second horizontal direction that is orthogonal to the first horizontal direction, wherein the first variable resistance pattern structure and the second variable resistance pattern structure are arranged in a diagonal direction with respect to each of the first horizontal direction and the second horizontal direction, and
wherein the first variable resistance pattern structure and the third variable resistance pattern structure are arranged in the first horizontal direction or the second horizontal direction.

13. The variable resistance memory device of claim 11, wherein the plurality of variable resistance pattern structures are arranged in a row and in zigzags in a first horizontal direction and a second horizontal direction that is orthogonal to the first horizontal direction, wherein the first variable resistance pattern structure and the second variable resistance pattern structure are arranged in the first horizontal direction or the second horizontal direction, and
wherein the first variable resistance pattern structure and the third variable resistance pattern structure are arranged in a diagonal direction with respect to each of the first horizontal direction and the second horizontal direction.

14. The variable resistance memory device of claim 11, wherein a bottom surface of the isolation recess is at a vertical level that is lower than a top surface of the protrusion and higher than a bottom surface of the isolation insulating layer, and
wherein a horizontal width of the isolation recess in a direction that extends between the first variable resistance pattern structure and the second variable resistance pattern structure is greater than a horizontal width of the isolation recess in a direction that extends between the first variable resistance pattern structure and the third variable resistance pattern structure.

15. The variable resistance memory device of claim 11, wherein an uppermost end of the isolation insulating layer, top surfaces of the plurality of lower electrode contacts, and bottom surfaces of the plurality of variable resistance pattern structures are at a substantially same vertical level as each other and are at a vertical level that is higher than a top surface of the protrusion.

16. The variable resistance memory device of claim 15, wherein the bottom surfaces of the plurality of variable resistance pattern structures are disposed on top surfaces of the plurality of lower electrode contacts and top surfaces of portions of the isolation insulating layer that covers side surfaces of the plurality of lower electrode contacts.

17. The variable resistance memory device of claim 11, wherein the isolation insulating layer comprises a first isolation insulating layer and a second isolation insulating layer covering the first isolation insulating layer and including an insulating material with a dielectric constant that is lower than that of the first isolation insulating layer, and
wherein the isolation recess passes through the second isolation insulating layer, but does not pass through the first isolation insulating layer.

18. A variable resistance memory device comprising:
a substrate;
a plurality of wiring contacts arranged on the substrate;
a plurality of lower electrode contacts connected to the plurality of wiring contacts;
an isolation insulating layer covering sidewalls of the plurality of lower electrode contacts and disposed on the plurality of wiring contacts, wherein the isolation insulating layer includes a first isolation insulating layer and a second isolation insulating layer covering the first isolation insulating layer; and
a plurality of variable resistance pattern structures spaced apart from one another in a horizontal direction on the isolation insulating layer to form a plurality of memory cells, and connected to the plurality of lower electrode contacts, wherein the isolation insulating layer comprises a protrusion that is defined by an isolation recess, wherein, among the plurality of variable resistance pattern structures, a first variable resistance pattern structure is spaced apart from a second variable resistance pattern structure by a first distance and is spaced apart from a third variable resistance pattern structure by a second distance that is greater than the first distance in a direction that is different than a direction in which the distance extends, wherein the protrusion is not arranged between the first variable resistance pattern structure and the second variable resistance pattern structure, and is arranged between the first variable resistance pattern structure and the third variable resistance pattern structure, wherein an uppermost end of the isolation insulating layer and bottom surfaces of the plurality of variable resistance pattern structures are at a substantially same vertical level as each other, but are at a higher vertical level than a top surface of the protrusion, and
wherein a bottom surface of the isolation recess is at a vertical level that is lower than the top surface of the protrusion and higher than a bottom surface of the isolation insulating layer.

19. The variable resistance memory device of claim 18, wherein the second isolation insulating layer comprises an insulating material with a dielectric constant that is lower than that of the first isolation insulating layer, and
wherein the isolation recess passes through the second isolation insulating layer, but does not pass through the first isolation insulating layer.

20. The variable resistance memory device of claim 18, wherein the first isolation insulating layer comprises SiCN, and
wherein the second isolation insulating layer comprises silicon oxide.
